(19) United States
(12) Patent Application Publication
(10) Pub. No.: US 2015/0095871 A1
(43) Pub. Date: Apr. 2, 2015

(54) CIRCUIT DESIGN SUPPORT METHOD, COMPUTER PRODUCT, CIRCUIT DESIGN SUPPORT APPARATUS, AND SEMICONDUCTOR INTEGRATED CIRCUIT

(71) Applicant: FUJITSU SEMICONDUCTOR LIMITED, Yokohama-shi (JP)

(72) Inventor: Tomoyasu Kitaura, Kawasaki (JP)

(73) Assignee: Fujitsu Optical Components Limited, Kawasaki (JP)

(21) Appl. No.: 14/497,876

(22) Filed: Sep. 26, 2014

(30) Foreign Application Priority Data
Oct. 2, 2013 (JP) 2013-207269

(51) Int. Cl. G06F 17/50; H01L 27/02

(52) U.S. Cl. CPC G06F 17/5077; H01L 27/0207; G06F 2217/62; G06F 2217/78; G06F 2217/84
USPC 716/129; 327/565

(57) ABSTRACT

A circuit design support method includes obtaining layout data that indicates positions of a plurality of clock receivers disposed in a circuit and positions of first clock wires disposed in the circuit; and calculating, by a computer, a value corresponding to lengths of wires respectively connecting the clock receivers to second clock wires on the basis of the obtained layout data, the value being calculated for each of a plurality of combinations of a count of the second clock wires and positions of the second clock wires, the second clock wires being disposed in a wiring layer of the circuit and being perpendicular to the first clock wires.

### CROSS REFERENCE TO RELATED APPLICATIONS

This application is based upon and claims the benefit of priority of the prior Japanese Patent Application No. 2013-207269, filed on Oct. 2, 2013, the entire contents of which are incorporated herein by reference.

### FIELD

The embodiments discussed herein are related to a circuit design support method, a computer product, a circuit design support apparatus, and a semiconductor integrated circuit.

### BACKGROUND

Clock mesh design is known as a type of clock wiring design for a semiconductor integrated circuit. In the clock mesh design, clock wires are disposed at constant intervals in horizontal and vertical directions to be in a grid. Outputs of plural clock drivers are short-circuited to the clock wires in the horizontal or the vertical direction and therefore, the clock mesh design can reduce differences in the clock skew.

According to a known technique, in the clock mesh design, the position of a clock buffer is determined to reduce, for example, the clock skew (see, e.g., Japanese Laid-Open Patent Publication No. 2007-300067). According to another technique, a clock supply circuit is disposed in a central portion of logic circuits; a wide-width main wire is formed on the logic circuits as upper layer wiring; and branched wires from the main wire are formed taking into consideration the position relation of the logic circuits, as the upper layer wiring (see, e.g., Japanese Laid-Open Patent Publication No. H5-121548). According to another technique, a block bus is wired to surround a circuit block to which a clock signal is supplied; and thereby, a gate array is realized having small clock skew in the wiring from the clock driver (see, e.g., Japanese Laid-Open Patent Publication No. H5-267625).

In the clock mesh design, however, the clock wires are disposed at constant intervals and therefore, the wiring amount of the clock wires may be large.

### SUMMARY

According to an aspect of an embodiment, a circuit design support method includes obtaining layout data that indicates positions of a plurality of clock receivers disposed in a circuit and positions of first clock wires disposed in the circuit; and calculating, by a computer, a value corresponding to lengths of wires respectively connecting the clock receivers to second clock wires on the basis of the obtained layout data, the value being calculated for each of a plurality of combinations of a count of the second clock wires and positions of the second clock wires, the second clock wires being disposed in a wiring layer of the circuit and being perpendicular to the first clock wires.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is an explanatory diagram of an example of operations of a design support apparatus according to an embodiment;

FIG. 2 is a block diagram of a hardware configuration example of the circuit design support apparatus according to the embodiment;

FIG. 3 is a block diagram of a functional configuration of the design support apparatus;

FIG. 4 is an explanatory diagram of an example of an arrangement of horizontal trunk wires;

FIG. 5 is an explanatory diagram of a first division example;

FIG. 6 is an explanatory diagram of a second division example;

FIG. 7 is an explanatory diagram of an arrangement example of a vertical trunk wire in a case where the vertical trunk wire count is one;

FIG. 8 is an explanatory diagram of a grouping example of receivers in a case where the vertical trunk wire count is two;

FIGS. 9, 10, 11, and 12 are explanatory diagrams of arrangement examples of the vertical trunk wires in a case where the vertical trunk wire count is two;

FIG. 13 is an explanatory diagram of a first grouping example of the receivers in a case where the vertical trunk wire count is three;

FIG. 14 is an explanatory diagram of a first arrangement example of the vertical trunk wires in a case where the vertical trunk wire count is three;

FIG. 15 is an explanatory diagram of a second grouping example of the receivers in a case where the vertical trunk wire count is three;

FIG. 16 is an explanatory diagram of a second arrangement example of the vertical trunk wires when the vertical trunk wire count is three;

FIG. 17 is an explanatory diagram of a third arrangement example of the vertical trunk wires when the vertical trunk wire count is three;

FIG. 18 is a flowchart of a procedure example of a design support process executed by the design support apparatus;

FIG. 19 is a flowchart of a procedure example of a determination process executed by the design support apparatus according to the first example;

FIG. 20 is a flowchart of a procedure example of a function process executed by the design support apparatus;

FIG. 21 is a flowchart of a procedure for an evaluation process executed for the group A;

FIG. 22 is a flowchart of a procedure for the evaluation process for the group B;

FIG. 23 is an explanatory diagram of an arrangement example of the vertical trunk wires in a case where the vertical trunk wire count is five;

FIG. 24 is an explanatory diagram of an arrangement example of the vertical trunk wires in a case where the vertical trunk wire count is four;

FIG. 25 is an explanatory diagram of an arrangement example of the vertical trunk wires when the vertical trunk wire count is three;

FIG. 26 is an explanatory diagram of an arrangement example of the vertical trunk wires in a case where the vertical trunk wire count is two;

FIG. 27 is an explanatory diagram of an arrangement example of the vertical trunk wires in a case where the vertical trunk wire count is one;

FIG. 28 is a flowchart of an example of the procedure for the determining process executed by the design support apparatus according to a second example;

FIG. 29 is an explanatory diagram of a configuration example of clock wires;

FIG. 30 is an explanatory diagram of an example of a pre-mesh tree;

FIG. 31 is an explanatory diagram of an example where the pre-mesh tree and clock mesh wires are overlapped with each other;

FIG. 32 is an explanatory diagram of a configuration example of the clock mesh wires and drivers;

FIG. 33 is an explanatory diagram of a configuration example of the clock mesh wires, receivers, and the drivers;

FIG. 34 is an explanatory diagram of a configuration example of wires from the clock mesh wires to the FFs;

FIG. 35 is an explanatory diagram of a layer structure example;

FIG. 36 is a three-dimensional explanatory diagram of a structure example of the clock mesh wiring for a case where the vertical trunk wires are regularly disposed;

FIG. 37 is a three-dimensional explanatory diagram of a structure example of the clock mesh wires for a case where the vertical trunk wires in the embodiment are disposed;

FIG. 38 is a three-dimensional explanatory diagram of a structure example of the pre-mesh tree;

FIG. 39 is a three-dimensional explanatory diagram of a structure example of horizontal trunk wires and the drivers;

FIG. 40 is a three-dimensional explanatory diagram of a structure example of the clock mesh wires, the drivers, and the receivers; and

FIG. 41 is a three-dimensional explanatory diagram of a structure example of the clock mesh wires, the receivers, and FFs.

### DESCRIPTION OF EMBODIMENTS

Embodiments of a circuit design support method, a computer product, a circuit design support apparatus, and a semiconductor integrated circuit will be described in detail with reference to the accompanying drawings.

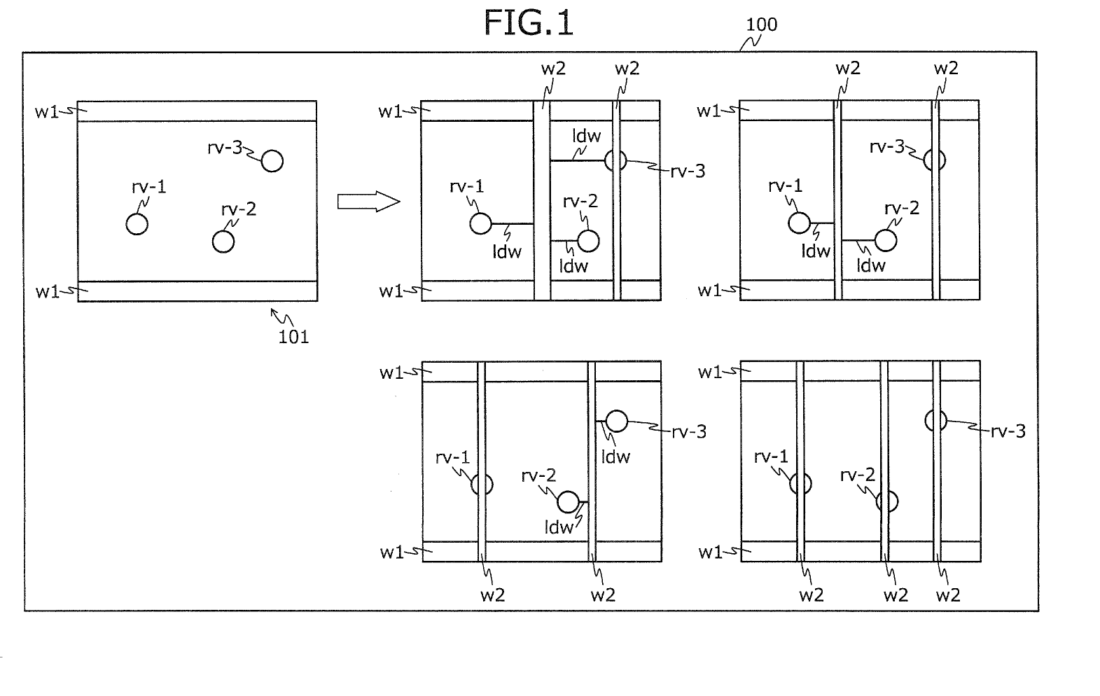

FIG. 1 is an explanatory diagram of an example of operations of the design support apparatus according to an embodiment. The design support apparatus 100 is a computer that supports the design of clock mesh wiring. The design support apparatus 100 obtains layout data 101 that indicates the positions of plural clock receivers “rv” disposed in a circuit under design and positions of first clock wires w1 disposed in the circuit under design. The “circuit under design” refers to a circuit disposed in a partial area formed by dividing a predetermined area having a circuit block disposed therein in the circuit to be designed. Clock receivers rv-1 to rv-3 are each a type of clock driver, and each is a cell that outputs a clock signal to a cell receiving the clock signal such as a flip flop (FF) in the clock mesh wiring. Hereinafter, the clock receiver rv will be referred to as “receiver rv” and the clock driver will be referred to as “driver”.

Based on the obtained layout data 101, the design support apparatus 100 calculates for each of plural combinations, an evaluation value corresponding to the lengths of the wires connecting each of the plural receivers rv-1 to rv-3 to any one of second clock wires w2. The combinations are formed by the number of second clock wires w2 and the positions thereof. The second clock wires w2 are clock wires disposed in a wiring layer of the circuit under design different from a wiring layer of first clock wires w1; are clock wires whose direction is perpendicular to that of the first clock wires w1; and each is connected between the first clock wires w1. In FIG. 1, four combinations will be taken as an example. Each of wires connecting each of the plural receivers rv-1 to rv-3 to any one of the second clock wires w2 will be referred to as “leading wire 2dw”.

For example, the design support apparatus 100 determines the number of second clock wires w2; determines the positions of the determined number of second clock wires; based on the determined positions, determines for each of the receivers rv, the second clock wire connected thereto; and thereafter, calculates the evaluation value based on the positions of the receivers rv to be connected and the positions of the second clock wires. Alternatively, for example, the design support apparatus determines the number of the second clock wires w2; determines for each of the receivers rv, which one of the second clock wires is connected thereto; determines the positions of the second clock wires corresponding to the centers of gravity of the positions of the receivers rv to be connected; and thereafter, calculates the evaluation value based on the positions of the receivers rv to be connected and the positions of the second clock wires.

For example, the evaluation value corresponding to the lengths is the total length of the leading wires 1dw. For example, for each of the plural combinations, the design support apparatus 100 may calculate the total value of the total length of the leading wires 1dw and the total length of the second clock wires w2, as the evaluation value. For each of the plural combinations, the design support apparatus 100 calculates the total capacitance value of the leading wires 1dw based on the widths of the leading wires 1dw and a value corresponding to the calculated length; and calculates the total capacitance value of the second clock wires w2, based on the wire widths of the second clock wires w2 determined corresponding to the number of second clock wires w2 and the total length of the second clock wires w2. The design support apparatus 100 may calculate the total value of the two total capacitance values as the evaluation value. For example, it is assumed that a reference wire width is determined in advance for a case where the number of second clock wires w2 is one and the wire width of each of the second clock wires w2 is a value obtained by dividing the reference wire width by the number of second clock wires w2. Thus, the value of the combined resistance of the second clock wires w2 between the first clock wires w1 in the partial area can be set to be constant regardless of the number of second clock wires w2, whereby differences can be reduced and consequently differences in clock skew can be further reduced.

As described, the design support apparatus 100 calculates the evaluation value for each of the plural combinations of the number of second clock wires w2 and the positions thereof. Thereby, the number of the second clock wires w2 and the positions thereof with a small wiring amount can be selected. Therefore, reduction of the wiring amount can be facilitated. The resistance value and the capacitance value of the clock mesh wiring can be reduced and differences in clock skew can be reduced.

For example, the design support apparatus 100 can cause a storing apparatus accessible by the design support apparatus 100 to correlate and store therein each of the combinations and the evaluation value calculated therefor.

The design support apparatus 100 selects any one of the plural combinations based on the evaluation value calculated for each of the plural combinations. When the evaluation value corresponding to the length represents the total length of the wires, the design support apparatus 100 selects the combination whose calculated total length is the shortest. For example, the design support apparatus 100 causes a storage apparatus accessible by the design support apparatus 100 to store therein the selection result as the optimal combination.

The number of second clock wires w2 is set to be less than or equal to the number of plural receivers rv. Thereby, the number of combinations can be reduced and the speed of the calculation process executed by the design support apparatus can be increased.

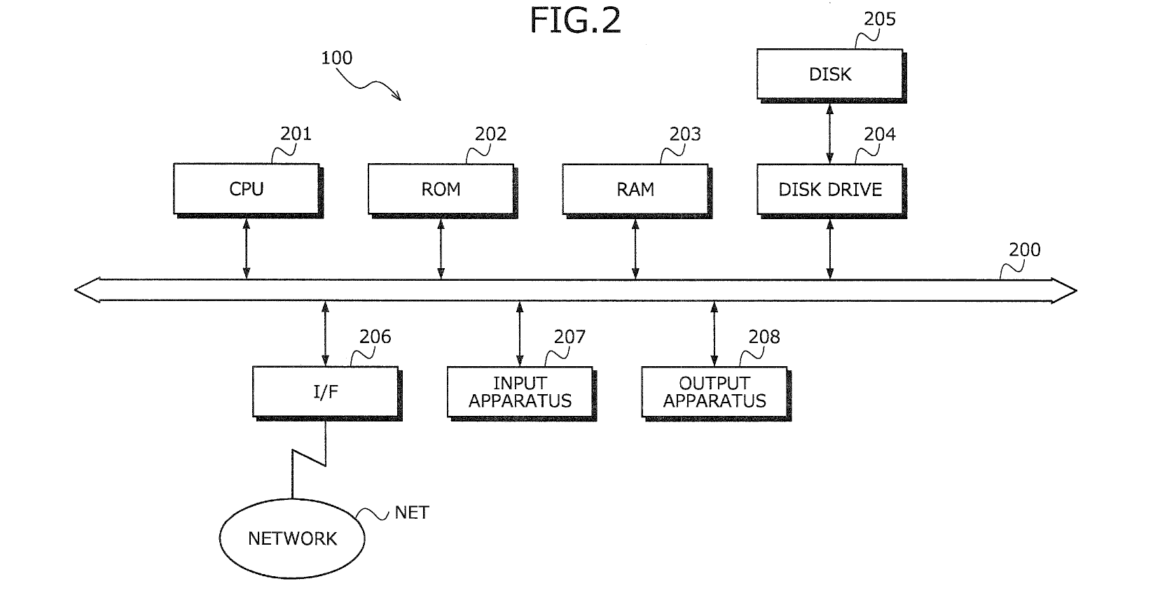

FIG. 2 is a block diagram of a hardware configuration example of the circuit design support apparatus according to the embodiment. In FIG. 2, the circuit design support apparatus 100 includes a central processing unit (CPU) 201, read-only memory (ROM) 202, random access memory (RAM) 203, a disk drive 204, a disk 205, an interface (I/F) 206, an input apparatus 207, and an output apparatus 208, respectively connected by a bus 200.

The CPU 201 governs overall control of the circuit design support apparatus 100. The ROM 202 stores programs such as a boot program. The RAM 203 is used as a work area of the CPU 201. The disk drive 204, under the control of the CPU 201, controls the reading and writing of data with respect to the disk 205. The disk 205 stores data written thereto under the control of the disk drive 204. The disk 205 may be a magnetic disk, an optical disk, and the like.

The I/F 206 is connected through a communications lines to network NET, such as a local area network (LAN), a wide area network (WAN), and the Internet, and is connected to other devices through the network NET. The I/F 206 administers an internal interface with the network NET, and controls the input and output of data with respect to external devices. For example, a modem or LAN adapter may be employed as the I/F 206.

The input apparatus 207 is an interface that input various types of data by user operation of a keyboard, touch panel, etc. Further, the input apparatus 207 can take in images and video from a camera. The input apparatus 207 can further take in sound from a microphone. The output apparatus 208 is an interface that outputs data consequent to an instruction by the CPU 201. The output apparatus 208 may be a display, printer, and the like.

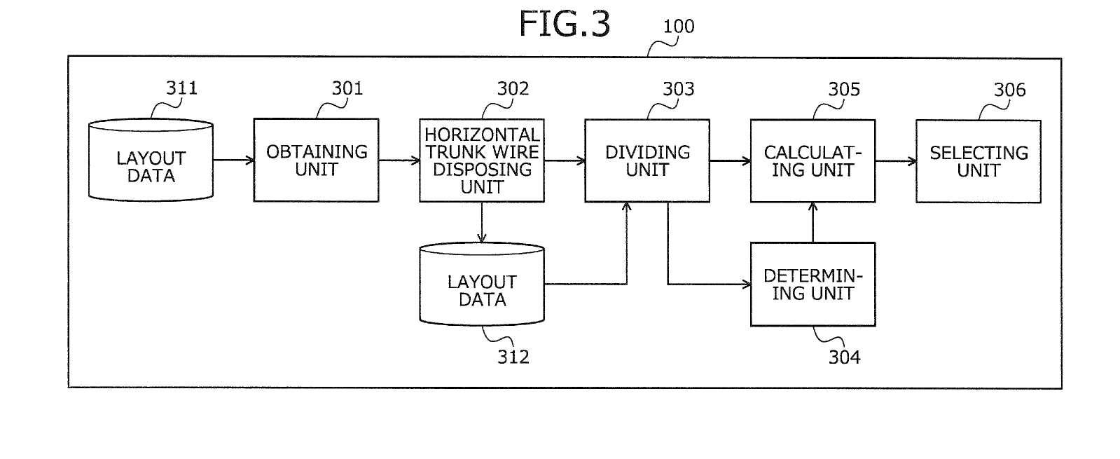

FIG. 3 is a block diagram of a functional configuration of the design support apparatus. The design support apparatus 100 includes an obtaining unit 301, a horizontal trunk wire disposing unit 302, a dividing unit 303, a determining unit 304, a calculating unit 305, and a selecting unit 306. Processes executed by the units are coded in, for example, a circuit design support program stored in a storing apparatus accessible by the CPU 201. The CPU 201 reads the circuit design support program from a storage apparatus and executes the processes coded in the circuit design support program. Thereby, the processes executed by the units are implemented. The results of the processes executed by the units are stored in a storing apparatus such as, for example, a RAM 203 or a disk 205.

The obtaining unit 301 obtains layout data 311 indicating the drivers and the receivers rv disposed in the predetermined area in the circuit to be designed and the positions of the drivers and the receivers rv. The “predetermined area” is an area in which, for example, a circuit block in the circuit to be designed is disposed. A cell such as an FF cell in the circuit block receives input of a clock signal from the clock supply circuit through a clock wire, a driver, etc. The “driver” refers to a driver dr for a buffer. The “receiver rv” refers to a buffer, etc., and is connected to a cell such as the FF that executes synchronization according to the clock signal.

Based on the obtained layout data 311, the trunk wire disposing unit 302 produces layout data 312 that indicates the first clock wires based on the positions of the drivers dr indicated by the obtained layout data, and the positions of the first clock wires. The first clock wire will be referred to as “horizontal trunk wire”.

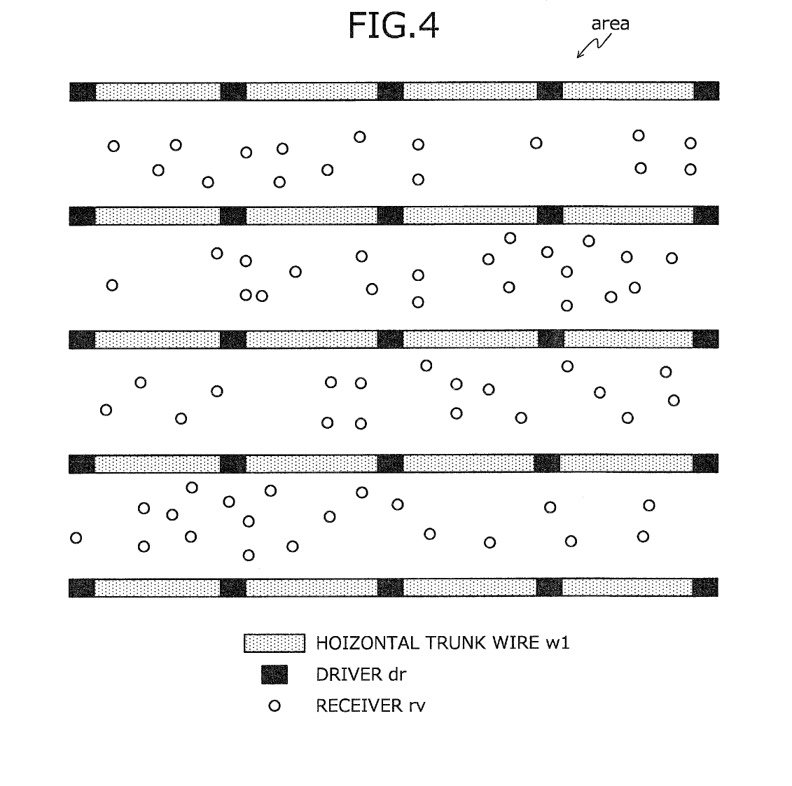

FIG. 4 is an explanatory diagram of an example of the arrangement of the horizontal trunk wires. As depicted in FIG. 4, the drivers dr and the receivers rv are disposed in the predetermined area “area”. The horizontal trunk wires w1 are disposed such that output of the drivers dr whose vertical positions are the same are connected by the horizontal trunk wires w1. In the clock mesh scheme, the clock signal is driven by the plural drivers dr and therefore, the clock skew can be reduced.

The obtaining unit 301 obtains the layout data 311 that indicates the drivers dr and the receivers rv disposed in the predetermined area “area” in the circuit to be designed, the positions of the drivers dr and the receivers rv, the horizontal trunk wires w1, and the positions of the horizontal trunk wires w1.

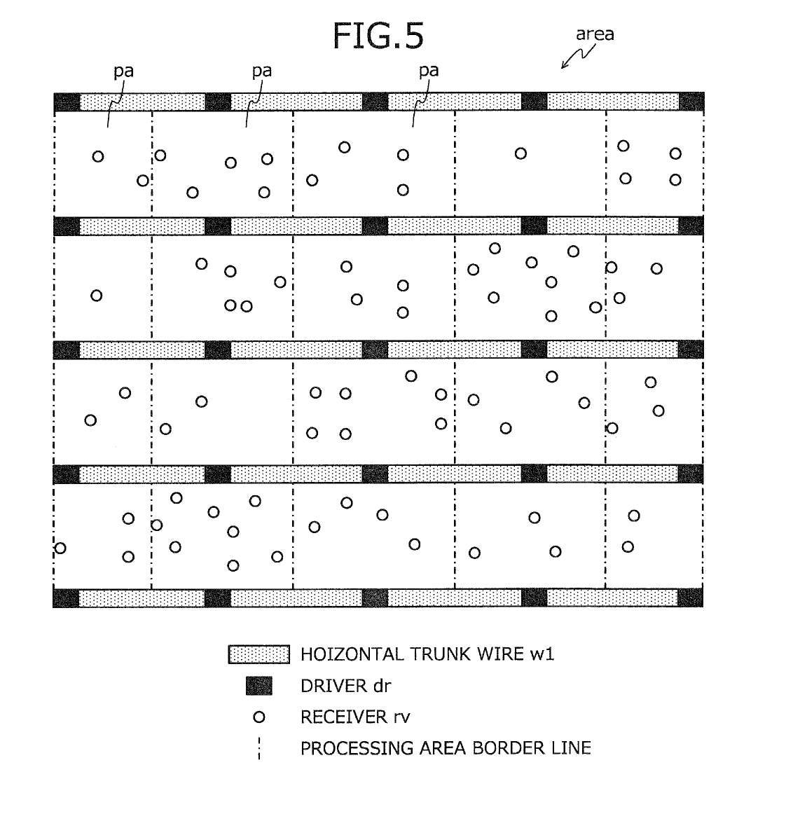

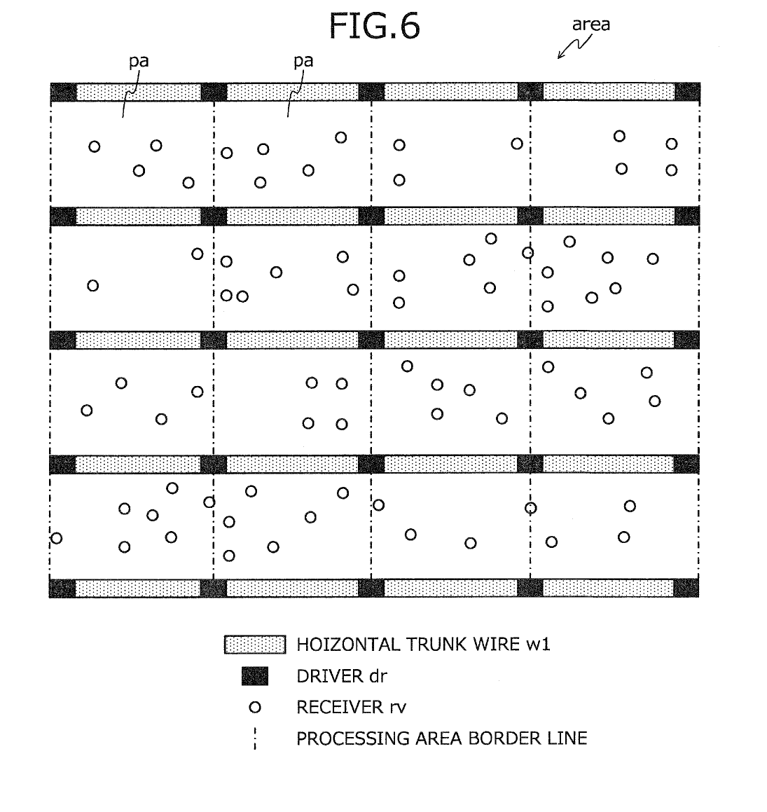

Based on the obtained layout data 311, the dividing unit 303 produces area information that indicates each of plural areas “pa” formed by dividing the predetermined area “area” in the circuit to be designed. The area information includes the coordinates of the vertices of each of areas “pa”. For example, FIGS. 5 and 6 each depict a division example.

FIG. 5 is an explanatory diagram of the first division example. As depicted in FIG. 5, the dividing unit 303 divides using the midpoint between the drivers dr close to each other as a border and using the area “pa” between each of the horizontal trunk wires w1 and the border as a unit. A dotted and dashed line represents the border.

FIG. 6 is an explanatory diagram of the second division example. As depicted in FIG. 6, the dividing unit 303 divides using the driver dr as a border and using the area “pa” between each of the horizontal trunk wires w1 and the border as a unit. A dotted and dashed line represents the border.

When the distance between the drivers dr is less than or equal to a predetermined distance, the dividing unit 303 may consolidate the plural areas “pa” to form one area “pa”. The “predetermined distance” is, for example, a value determined in advance by a user. As described, the size of each area “pa” can be formed to be not too small.

Although the obtaining unit 301 obtains the layout data 311 before the division above, layout data concerning each divided area “pa” may be obtained.

Based on the layout data 311, the calculating unit 305 calculates a value corresponding to the lengths of the wires that connect each of the plural receivers rv to any one of the second clock wires, for each of the plural combinations of the number of second clock wires and the positions thereof. The second clock wires are clock wires disposed in a wiring layer different from the wiring layer of the horizontal trunk wires w1 indicated by the layout data 311, and are clock wires whose direction is perpendicular to that of the first clock wires. The second clock wires will be referred to as “vertical trunk wires w2”. For example, the vertical trunk wire w2 count N is set to be a count “N”. For example, the vertical trunk wire w2 count N is set to be is less than or equal to the number of receivers rv in the area “pa”. The calculating unit 305 calculates an evaluation value for each of the plural combinations of the vertical trunk wire w2 count N and the vertical trunk wire w2 positions based on the centers of gravity of the receivers rv connected to the vertical trunk wires w2. The “vertical trunk wire w2 positions based on the centers of gravity of the receivers rv” refers to, for example, positions overlapping with the centers of gravity. For example, the determining unit 304 determines the plural combinations. The determining unit 304, the calculating unit 305, and the selecting unit 306 will be described in detail with reference to first and second examples.

In the first example, the combinations are recursively determined, sequentially increasing the vertical trunk wire w2 count N from one; the evaluation value for each of the determined combination is calculated; and thereby, the vertical trunk wire w2 count N and the vertical trunk wire w2 positions with a small wiring amount is determined.

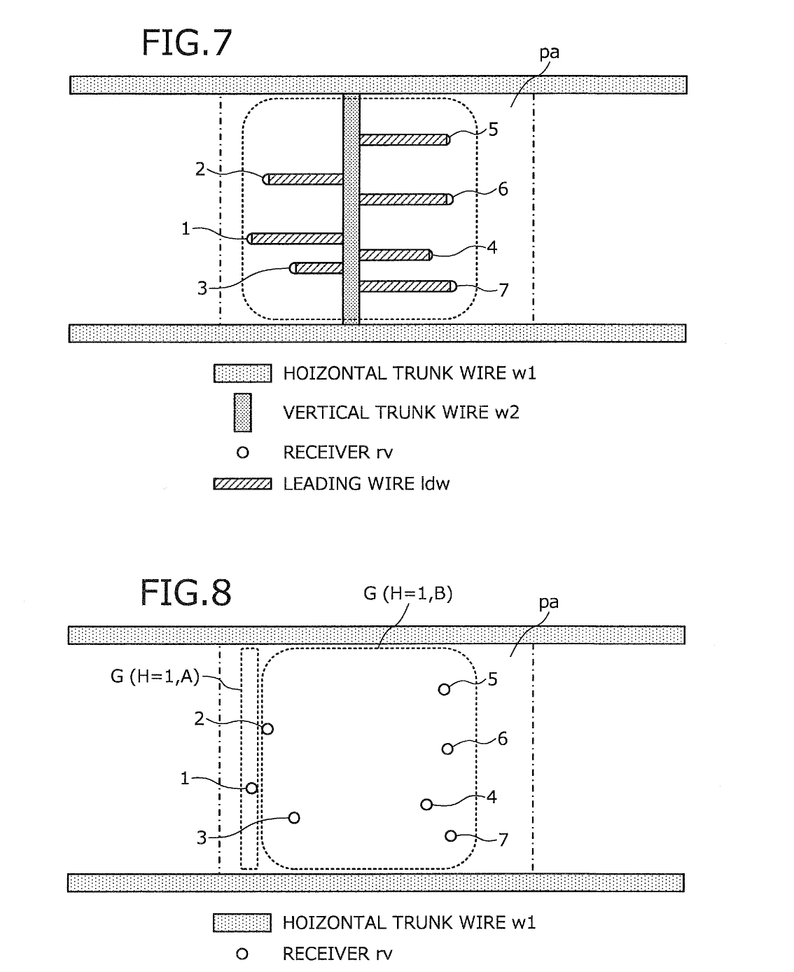

FIG. 7 is an explanatory diagram of an arrangement example of the vertical trunk wire in a case where the vertical trunk wire count is one. The determining unit 304 determines the position of the vertical trunks wire w2 in a case where the number of vertical trunk wires w2 is one. For example, the position of the vertical trunk wire w2 is set at the position of the centroid of X-coordinates of the receivers rv in the area pa. In this case, it is assumed that the wire width of the vertical trunk wire w2 is determined in advance in a case where the vertical trunk wire w2 count N is one. For example, the position of the vertical trunk wire w2 is set at the position of the centroid of X-coordinates of the receivers rv whose distances from the horizontal trunk wire w1 are each greater than or equal to the predetermined distance, among the receivers rv in the area pa. It is assumed that the predetermined distance is stored in advance in a storage apparatus such as the disk 205. As described, the receivers rv whose distances from the horizontal trunk wires w1 are each small are wired to the horizontal trunk wires w1 and may be removed from the conditions to determine the position of the vertical trunk wire w2.

When the vertical trunk wire w2 is disposed at the determined position, the calculating unit 305 calculates the evaluation value based on the length of the wire capable of connecting the vertical trunk wire w2 and the receiver rv. The evaluation value may be the wire length itself or may be a capacitance value of the wire based on the length and the width of the wire. It is assumed that the width of the wire is determined in advance. The combination of the vertical trunk wire w2 count N and the vertical trunk wire w2 positions, and the calculated evaluation value are correlated and stored in a storing apparatus such as the disk 205.

The positions of the vertical trunk wires w2 will be described for a case where the vertical trunk wire w2 count N is two. In a case where the vertical trunk wire w2 count N is greater than or equal to two, the determining unit 304 groups each of the receivers rv in the area pa in groups of the vertical trunk wire w2 count N. The determining unit 304 determines the vertical trunk wire w2 positions, based on the centers of gravity of the receivers rv included in the group. For a case where the vertical trunk wires w2 are disposed at the determined positions, the calculating unit 305 calculates the evaluation value based on the lengths of the wires capable of connecting the vertical trunk wires w2 and the receivers rv. The combinations of the vertical trunk wire w2 count N and the vertical trunk wire w2 positions, and the calculated evaluation value are correlated and stored in a storage apparatus such as the disk 205. In the embodiment, the determining unit 304 groups the receivers rv into groups A and B. The number of receivers rv included in the group A is represented by a count “m”. In the embodiment, the determining unit 304 hierarchizes the groups and produces a new group. The number of hierarchies is represented by a count “H”.

FIG. 8 is an explanatory diagram of a grouping example of the receivers in a case where the vertical trunk wire count is two. In the example depicted in FIG. 8, the vertical trunk wire w2 count N is two; the receiver rv count m is one; and the number of hierarchies is one. “G(H=1,A)” represents the group A and indicates that the hierarchy count H is one. “G(H=1,B)” represents the group B and indicates that the hierarchy count H is one. The group A includes, for example, the receiver rv-1. The group B includes, for example, the receivers rv-2 to rv-7.

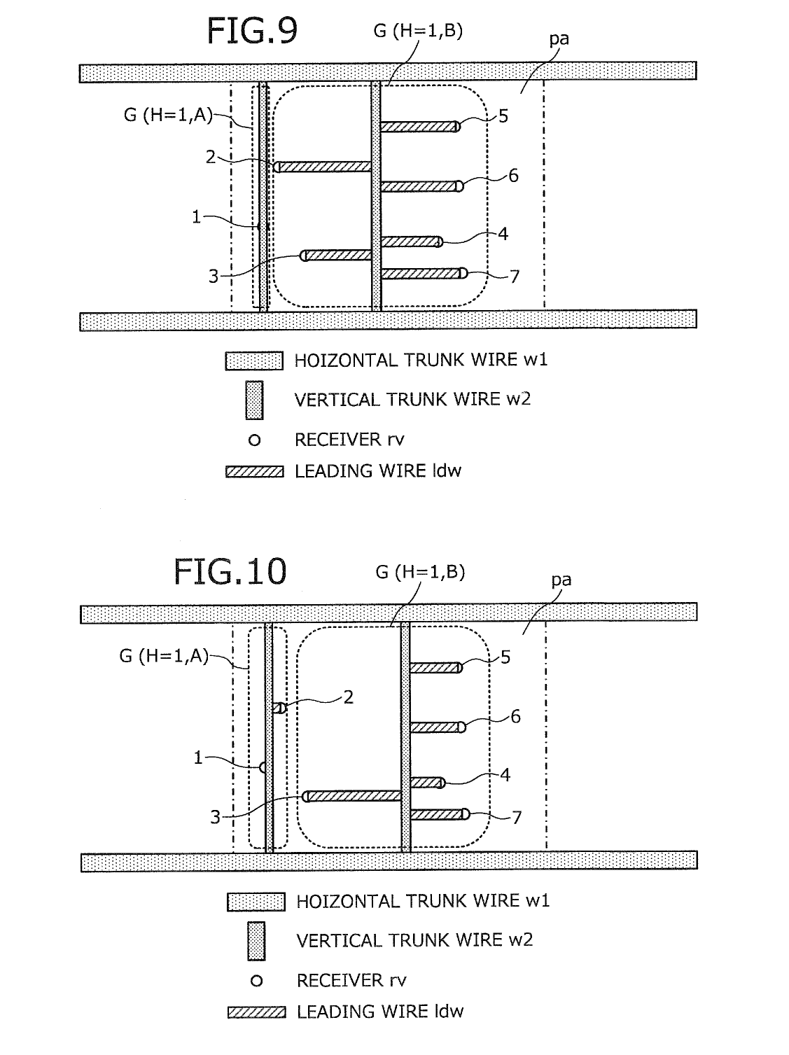

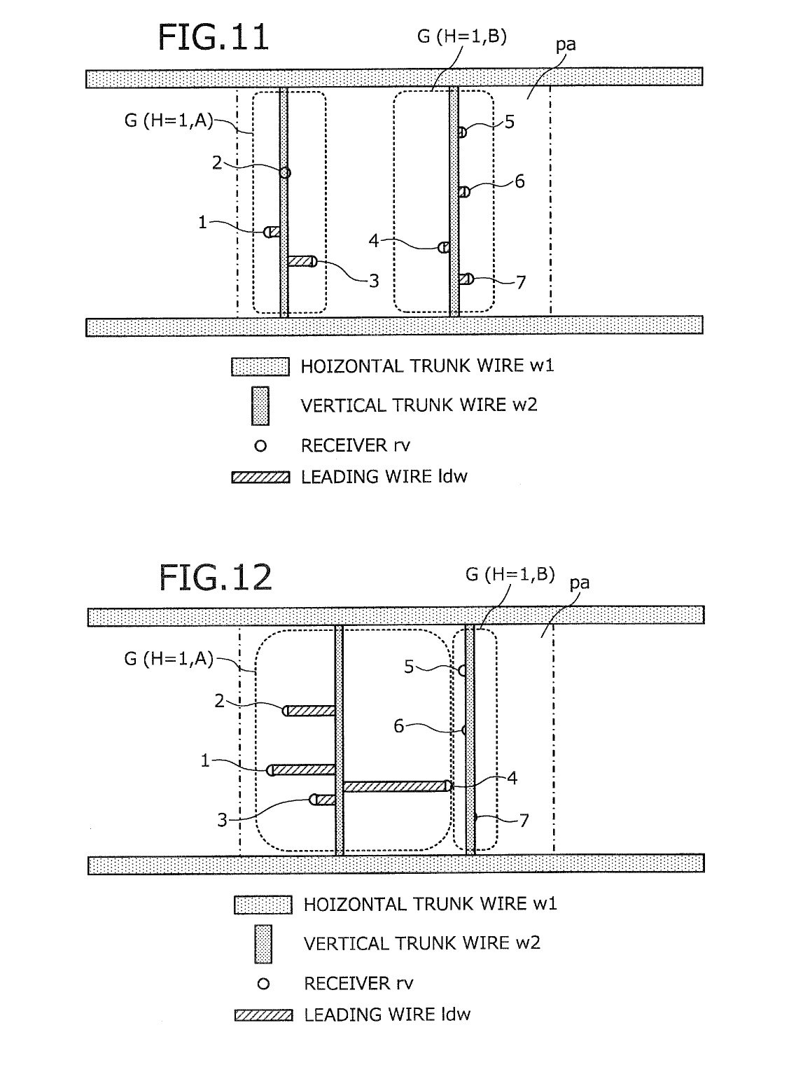

FIGS. 9, 10, 11, and 12 are explanatory diagrams of arrangement examples of the vertical trunk wires in a case where the vertical trunk wire w2 count N is two. For each of the groups, the determining unit 304 identifies the lengths of the leading wires 1dw that connect the vertical trunk wires w2 and the receivers rv when the vertical trunk wires w2 are disposed at the positions of the centers of gravity of the receivers rv included in the group. The wires connecting the vertical trunk wires w2 and the receivers rv will each be referred to as “leading wire 1dw”. The determining unit 304 calculates the evaluation value based on the lengths of the leading wires 1dw. In the example depicted in FIG. 9, for the group A, the length of the leading wire 1dw is zero because the group A includes only one receiver rv. The receiver rv count m is two in the example depicted in FIG. 10. The receiver rv count m is three in the example depicted in FIG. 11. The receiver rv count m is four in the example depicted in FIG. 12.

For example, the evaluation value for a case where the receiver rv count m is four is larger than that for a case where the receiver rv count m is three. In a case where the evaluation value is not reduced even when the receiver rv count m of the group A is increased for the hierarchy count H that is one, the selecting unit 306 selects an optimal combination in a case where the vertical trunk wire w2 count n is two. The determining unit 304 increases the vertical trunk wire w2 count n.

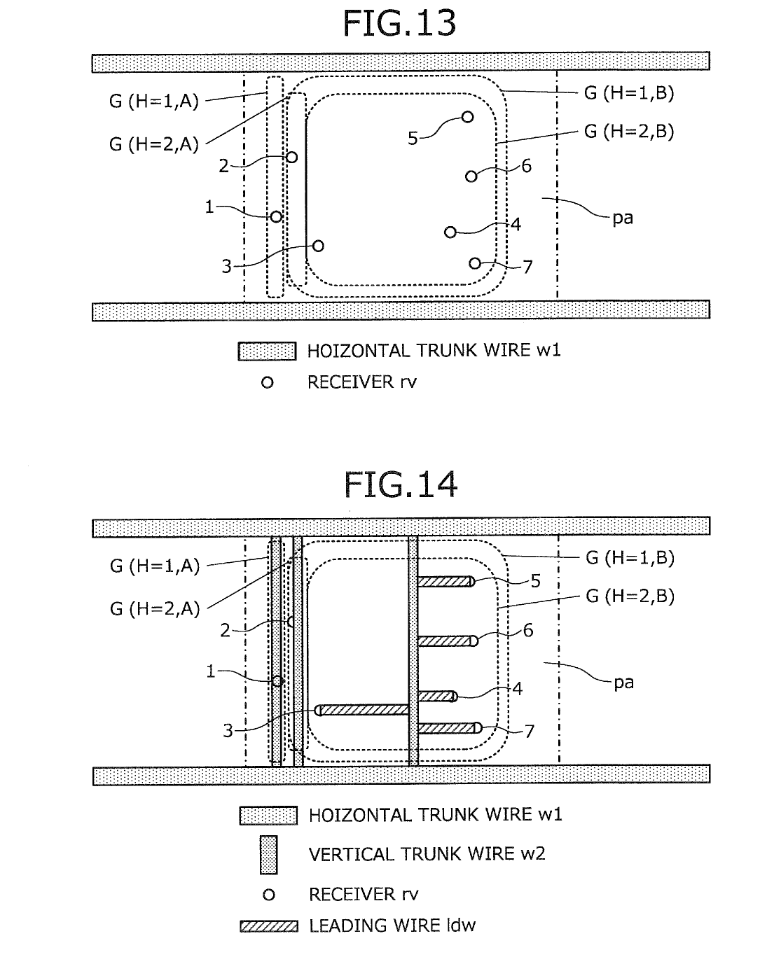

FIG. 13 is an explanatory diagram of a first grouping example of the receivers in a case where the vertical trunk wire count is three. In the example of FIG. 13, the receivers rv included in the group B in the case where the vertical trunk wire w2 count N is two depicted in FIG. 8 are grouped into the groups A and B in a hierarchy 2. Similar to FIGS. 9 to 12, the determining unit 304 also sequentially increases the receiver rv count m for the hierarchy count H of two from one to group the receivers rv included in the group B for the hierarchy count H of one. The calculating unit 305 similarly calculates the evaluation value.

FIG. 14 is an explanatory diagram of a first arrangement example of the vertical trunk wires in the case where the number of vertical trunk wires is three. In the example of FIG. 14, the vertical trunk wire w2 count N is three and, the receiver rv count m is one for the hierarchy count H of two.

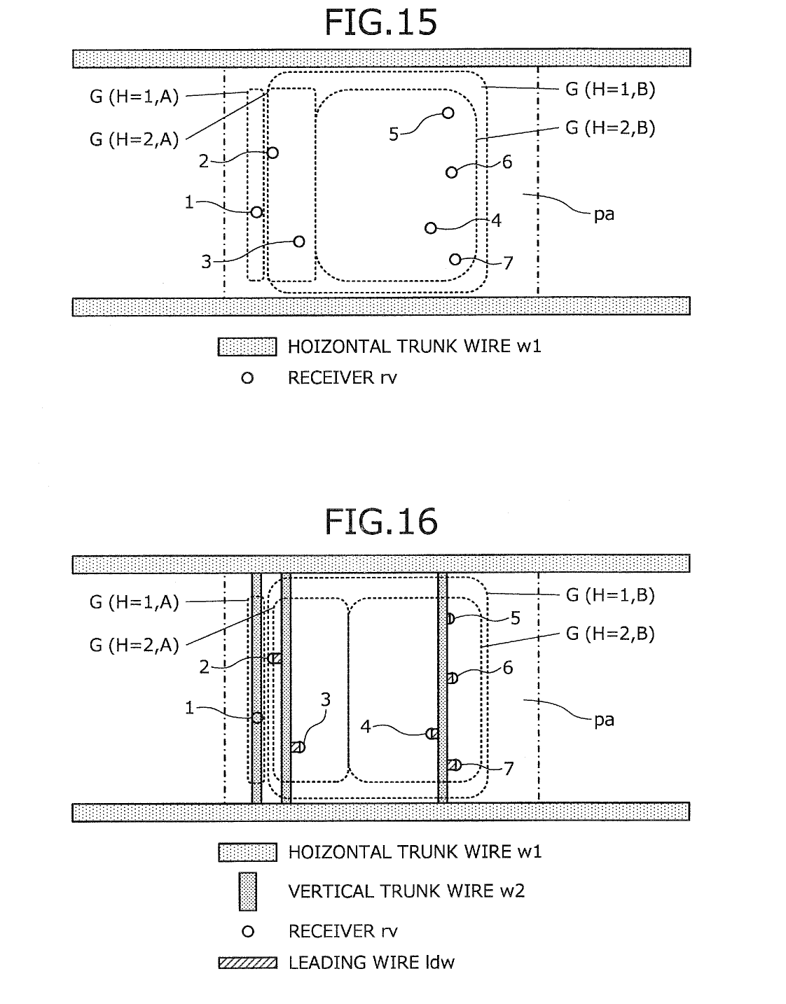

FIG. 15 is an explanatory diagram of a second grouping example of the receivers for a vertical trunk wire count of three. FIG. 16 is an explanatory diagram of a second arrangement example of the vertical trunk wires for a vertical trunk wire count of three. In the examples of FIGS. 15 and 16, the receiver rv count m is set to be two for the hierarchy count H of two and therefore, the receiver rv count m in the group A is two for the hierarchy count H that is two.

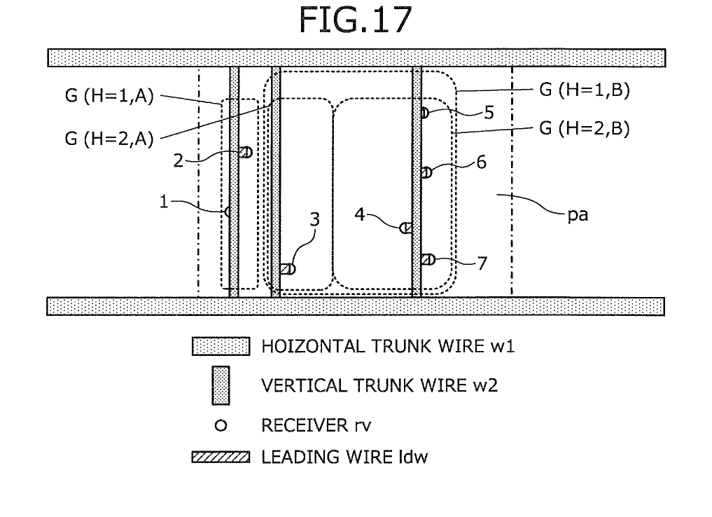

FIG. 17 is an explanatory diagram of a third arrangement example of the vertical trunk wires for a vertical trunk wire count of three. This is an example where two vertical trunk wires w2 are disposed for the receivers rv included in the group B when the receiver count m in the group A is two for the hierarchy count H of one.

As described, by recursively dividing the group B, the evaluation value is calculated for more combinations of the vertical trunk wire w2 count N and the vertical trunk wire w2 positions. For example, in a case where the evaluation value is not reduced even when the receiver rv count m in the group A is increased for the hierarchy count H of two, the selecting unit 306 selects the combination before the increase of the receiver rv count m as the optimal combination for the vertical trunk wire w2 count n of three. The selecting unit 306 compares the evaluation value for the optimal combinations for the selected vertical trunk wire w2 count n of two, with the evaluation value for the optimal combination for the selected vertical trunk wire w2 count n of three. When the evaluation value represents the total length of the leading wire 1dw and the vertical trunk wires w2, the selecting unit 306 selects the combination whose evaluation value is the smaller, as the optical combination.

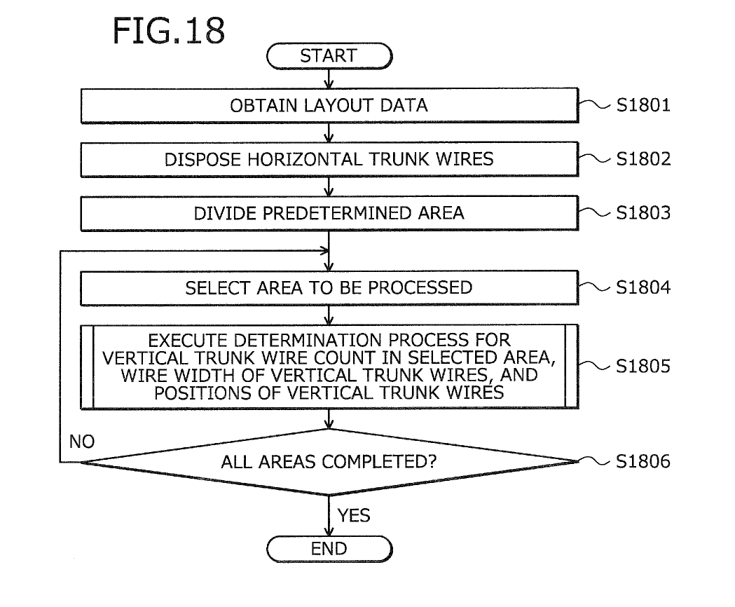

FIG. 18 is a flowchart of a procedure example of a design support process executed by the design support apparatus. The design support apparatus 100 obtains the layout data 311 (step S1801), disposes the horizontal trunk wires w1 (step S1802), divides the predetermined area “area” (step S1803), selects the area pa to be processed from the areas pa not to be processed of the divided plural areas pa (step S1804), executes a determination process for the vertical trunk wire w2 count N in the selected area pa, the wire width of the vertical trunk wires w2, and the positions of the vertical trunk wires w2 (step S1805), and determines whether the design support apparatus 100 has completed all the areas of the plural areas as those to be processed (step S1806). When the design support apparatus 100 determines that the design support apparatus 100 does not yet completed an area (step S1806: NO), the design support apparatus 100 returns to the operation at step S1804. When the design support apparatus 100 determines that the design support apparatus 100 has completed all the areas (step S1806: YES), the design support apparatus 100 causes the series of operations to come to an end.

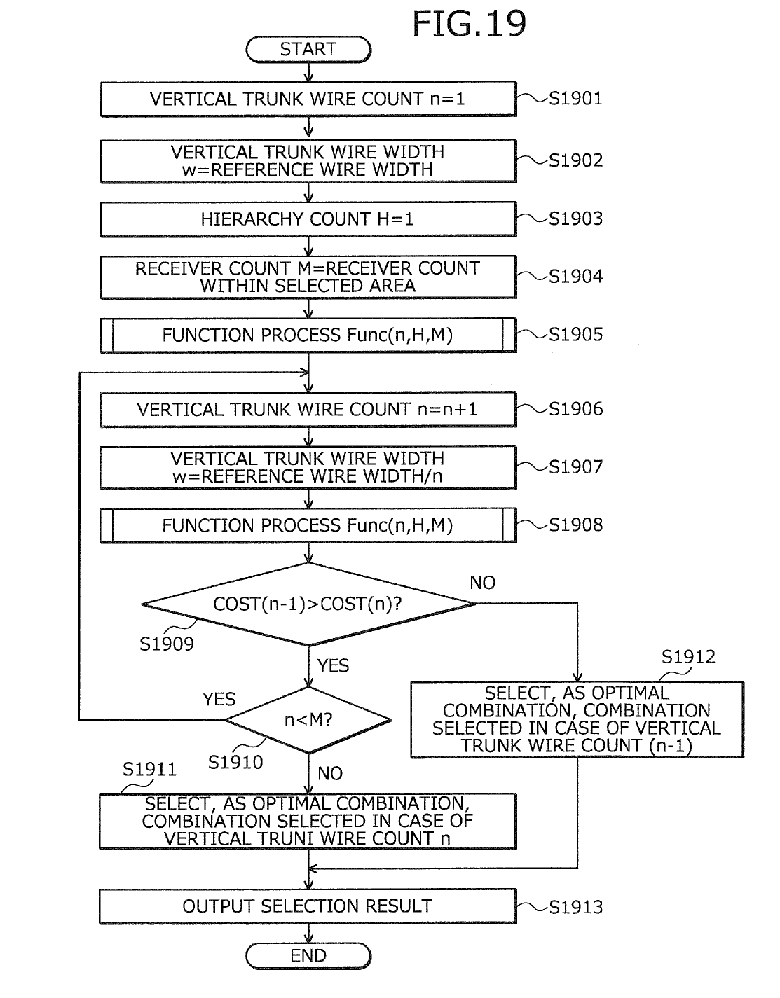

FIG. 19 is a flowchart of a procedure example of the determination process executed by the design support apparatus according to the first example. The design support apparatus 100 sets the count n of vertical trunk wire w2 to be n=1 (step S901), sets the wire width w of the vertical trunk wires w2 to be a reference wire width=w (step S1902). As described above, the reference wire width is determined in advance and is stored in a storage apparatus such as the disk 205.

The design support apparatus 100 sets the hierarchy count H to be H=1 (step S1903), sets the number M of receivers rv to be M=the number of receivers rv in the selected area pa (step S1904), and executes a function process Func(n,H,M) (step S1905). At step S1905, “( )” indicates arguments.

The design support apparatus 100 sets the vertical trunk wire w2 count n to be n=n+1 (step S1906), sets the wire width w of the vertical trunk wires w2 to be w=w/n (step S1907), executes the function process Func(n,H,M) (step S1908), determines whether COST(n−1) and COST(n) are COST(n−1)>COST(n) (step S1909). The return values of the function process Func are the vertical trunk wire w2 positions and the evaluation value thereof; and COST(n) is set as the evaluation value.

If the design support apparatus 100 determines that COST(n−1) and COST(n) are COST(n−1)>COST(n) (step S1909: YES), the design support apparatus 100 determines whether n and M are n<M (step S1910). If the design support apparatus 100 determines that n and M are n<M (step S1910: YES), the design support apparatus 100 returns to the operation at step S1906.

If the design support apparatus 100 determines that n and M are not n<M (step S1910: NO), the design support apparatus 100 selects the combination selected for the vertical trunk wire w2 count n in the case of n, as the optimal combination (step S1911) and advances to the operation at step S1913. On the other hand, if the design support apparatus 100 determines that COST(n−1) and COST(n) are not COST(n−1)>COST(n) (step S1909: NO), the design support apparatus 100 selects the combination selected for the vertical trunk wire w2 count n in the case of (n−1), as the optimal combination (step S1912), outputs the selection result (step S1913), and causes the series of operations to come to an end.

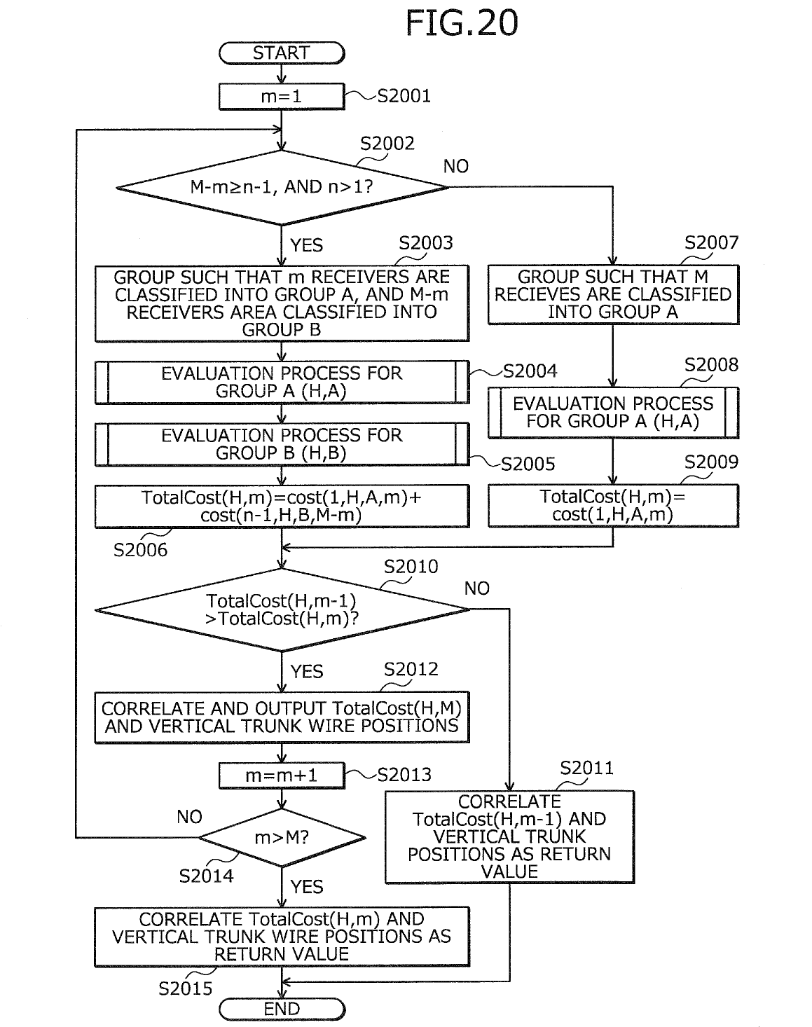

FIG. 20 is a flowchart of a procedure example of the function process executed by the design support apparatus. When the design support apparatus 100 executes the function process, the design support apparatus 100 accepts, as arguments, the vertical trunk wire w2 count n, the hierarchy count H, and the number M of receivers rv. The design support apparatus 100 sets m to be m=1 (step S2001), and determines whether M, m, and n are M−m≧n−1 and n>1 (step S2002).

When the design support apparatus 100 determines that M, m, and n are M−m≧n−1 and n>1 (step S2002: YES), the design support apparatus 100 forms groups such that m receivers rv are classified into the group A and M−m receivers rv are classified into the group B (step S2003), and executes an evaluation process (H,A) for the group A (step S2004). “H” is an argument. The design support apparatus 100 executes the evaluation process (H,B) for the group B (step S2005). “H” is an argument.

The design support apparatus 100 sets TotalCost(H,m) to be TotalCost(H,M)=cost(1,H,A,m)+cost(n−1,H,B,M−m) (step S2006), and advances to the operation at step S2010. On the other hand, when the design support apparatus 100 determines that M, m, and n are not M−m≧n−1 or n>1 (step S2002: NO), the design support apparatus 100 forms groups such that M receivers rv are classified into the group A (step S2007), executes the evaluation process (H,A) for the group A (step S2008), sets TotalCost(H,m) to be TotalCost(H,m)=cost(1,H,A,m) (step S2009), and advances to the operation at step S2010.

The design support apparatus 100 determines whether TotalCost(H,m−1) and TotalCost(H,m) are TotalCost(H,m−1)>TotalCost(H,m) (step S2010). If the design support apparatus 100 determines that TotalCost(H,m−1) and TotalCost(H,m) are not TotalCost(H,m−1)>TotalCost(H,m) (step S2010: NO), the design support apparatus 100 produces a return value by correlating TotalCost(H,m−1) and the vertical trunk wire w2 positions with each other (step S2011), returns the return value to the invoker, and causes the series of operations to come to an end.

On the other hand, if the design support apparatus 100 determines that TotalCost(H,m−1) and TotalCost(H,m) are TotalCost(H,m−1)>TotalCost(H,m) (step S2010: YES), the design support apparatus 100 correlates and outputs TotalCost(H,M) and the vertical trunk wire w2 positions (step S2012). The form of output may be output to a storage apparatus such as the RAM 203 or the disk 205. The design support apparatus 100 sets m to be m=m+1 (step S2013) and determines whether m and M are m>M (step S2014).

If the design support apparatus 100 determines that m and M are m>M (step S2014: YES), the design support apparatus 100 produces a return value by correlating TotalCost(H,m) and the vertical trunk wire w2 positions with each other (step S2015), returns the return value to the invoker, and causes the series of operations to come to an end. If the design support apparatus 100 determines that m and M are not m>M (step S2014: NO), the design support apparatus 100 returns to the operation at step S2002.

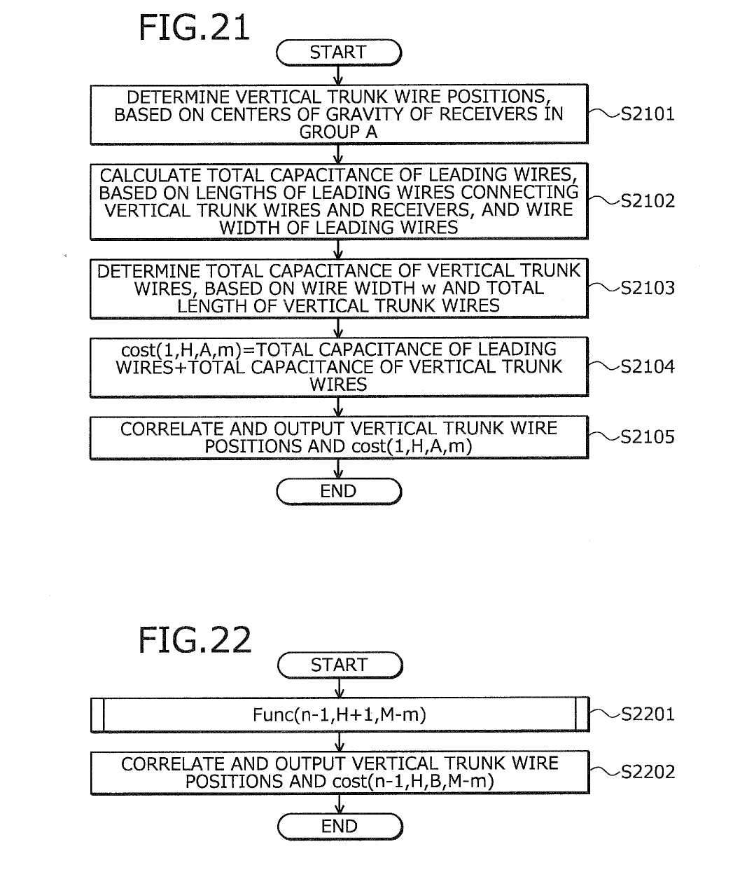

FIG. 21 is a flowchart of a procedure for the evaluation process executed for the group A. The design support apparatus 100 determines the vertical trunk wire w2 positions based on the centers of gravity of the receivers rv included in the group A (step S2101), and calculates the total capacitance value of the leading wires based on the lengths of the leading wires connecting the vertical trunk wires w2 and the receivers rv, and the wire width w of the leading wires (step S2102).

The design support apparatus 100 determines the total capacitance value of the vertical trunk wires w2 based on the wire width w of the vertical trunk wires w2 and the total length thereof (step S2103), defines cost(1,H,A,m) as cost(1,H,A,m)=the total capacitance value of the leading wires+the total capacitance value of the vertical trunk wires w2 (step S2104), outputs the vertical trunk wire w2 positions and cost(1,H,A,m) correlating these with each other (step S2105), and causes the series of operations to come to an end.

FIG. 22 is a flowchart of a procedure for the evaluation process for the group B. The design support apparatus 100 executes Func(n−1,H+1,M−m) (step s2201), correlates and outputs the vertical trunk wire w2 positions and cost(n−1,H,B,M−m) (step S2202), and causes the series of operations to come to an end.

In the second example, the combinations of the vertical trunk wire w2 positions and the vertical trunk wire w2 count N are determined, reducing the vertical trunk wire w2 count N by merging the groups with each other based on the distance between the receivers rv, and the evaluation value is calculated for each of the determined combinations.

The determining unit 304 determines the combinations of the vertical trunk wire w2 positions and the vertical trunk wire w2 count N thereof based on the distance between the receivers rv sequentially reducing the vertical trunk wire w2 count N from the number of receivers rv.

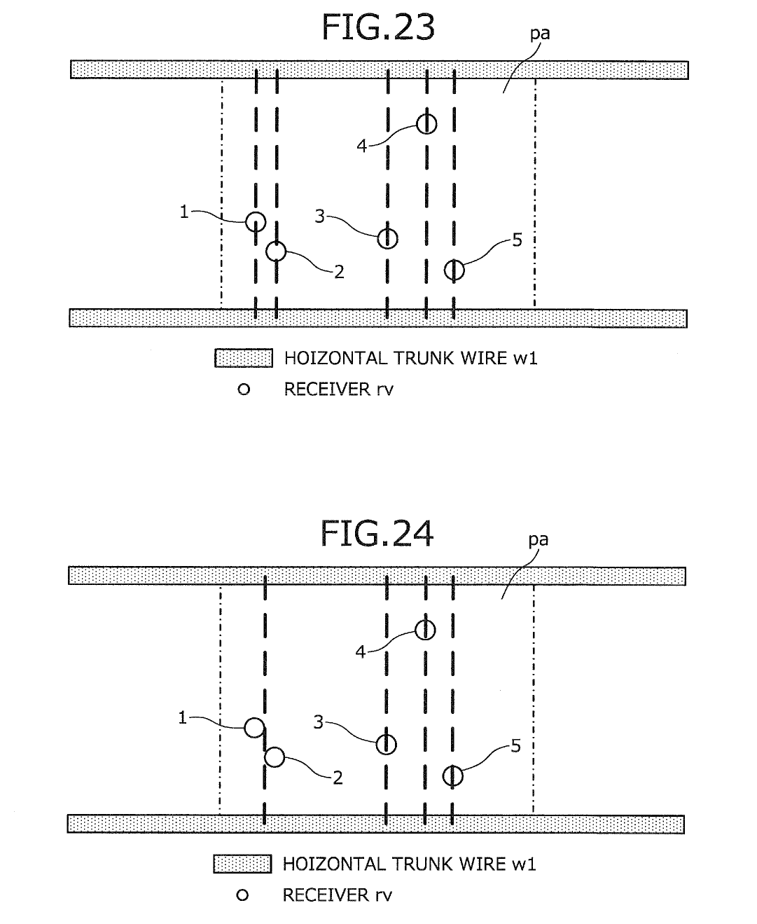

FIG. 23 is an explanatory diagram of an arrangement example of the vertical trunk wires for a vertical trunk wire count of five. The determining unit 304 forms five groups to group therein the receivers rv included in the area pa for the vertical trunk wire w2 count N of five, and determines for each of the groups, the vertical trunk wire w2 positions based on the centers of gravity of the positions of the receivers rv included in the group. The vertical trunk wires w2 positions based on the centers of gravity are the positions overlapping with the centers of gravity and, for example, the X-coordinates of the centers of gravity are equal to each other. The calculating unit 305 calculates the evaluation value based on the lengths of wires capable of connecting the vertical trunk wires w2 and the receivers rv in a case where the vertical trunk wires w2 are disposed at the determined positions. Concerning the evaluation value, description is the same as that of the first example.

FIG. 24 is an explanatory diagram of an arrangement example of the vertical trunk wires in a case where the vertical trunk wire count is four. For the vertical trunk wire w2 count n of four, the determining unit 304 consolidates into one of the groups whose X-coordinates of the receivers rv included in the groups are closest to each other and, thereby, groups the receivers rv included in the area pa into four groups. In this case, receivers rv-1 and rv-2 are included in the same group.

The determining unit 304 determines for each of the groups, the vertical trunk wire w2 positions based on the centers of gravity of the receivers rv included in the group. The calculating unit 305 calculates the evaluation value based on the lengths of the leading wires 1dw for the case where the vertical trunk wires w2 are disposed at the determined positions.

The selecting unit 306 compares the evaluation value for the combinations for the vertical trunk wire w2 count n of four, with the evaluation value for the combinations for the vertical trunk wire w2 count n of five. When the combination with the smaller evaluation value is the combination for the vertical trunk wire w2 count n that is the larger, the selecting unit 306 determines that the combination with the smaller evaluation value is the optimal combination. When the combination with the smaller evaluation value is the combination for the vertical trunk wire w2 count n that is the smaller, the selecting unit 306 causes the calculating unit 305 to calculate the evaluation value for the combination for the vertical trunk wire w2 count n less one. In this case, the evaluation value for the combination for the vertical trunk wire w2 count n of four is the smaller and therefore, the calculating unit 305 calculates the evaluation value for the combination for the vertical trunk wire w2 count n of three.

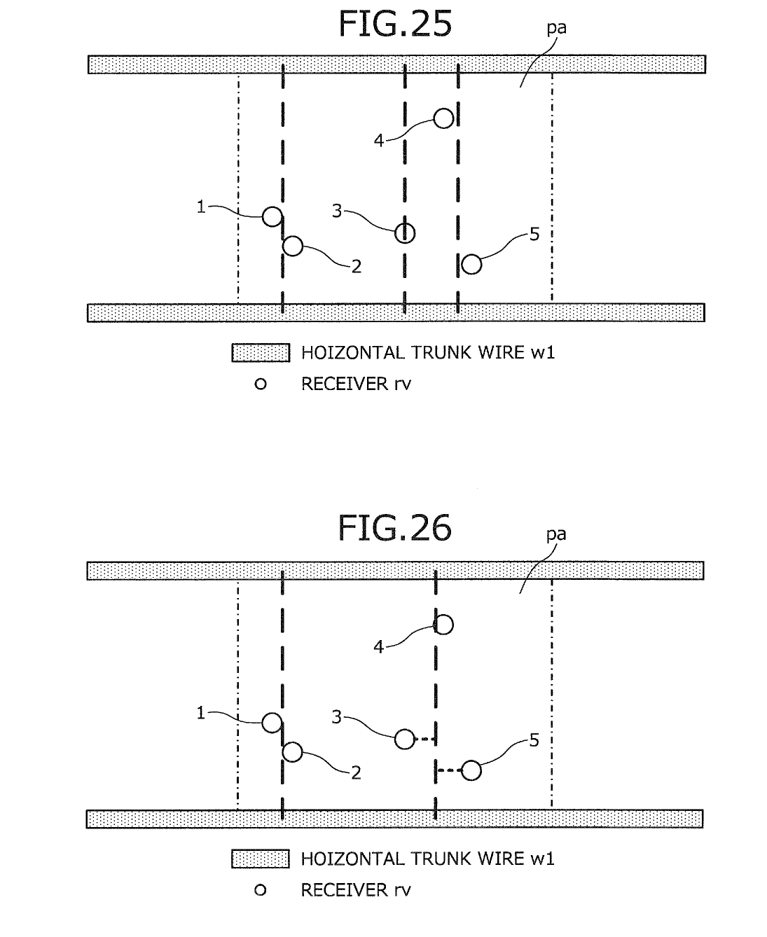

FIG. 25 is an explanatory diagram of an arrangement example of the vertical trunk wires for a vertical trunk wire count of three. For the vertical trunk wire w2 count n of three, the determining unit 304 consolidates into one of the groups whose receivers rv have the X-coordinates closest to each other included in the groups and thereby, forms groups the receivers rv included in that area pa into three groups. In this case, the receivers rv-4 and rv-5 are included in the same group. The calculating unit 305 calculates the evaluation value similar to the case of the vertical trunk wire w2 count n of four.

The selecting unit 306 compares the evaluation value for the combination for the vertical trunk wire w2 count n of four, with the evaluation value for the combination for the vertical trunk wire w2 count n of three. In this case, the evaluation value is smaller for the combination for the vertical trunk wire w2 count n of three and therefore, the calculating unit 305 calculates the evaluation value for the combination for the vertical trunk wire w2 count n of three.

FIG. 26 is an explanatory diagram of an arrangement example of the vertical trunk wires for a vertical trunk wire count of two. For the vertical trunk wire w2 count n of two, the determining unit 304 consolidates into one of the groups whose X-coordinates of the receivers rv included in the groups are closest to each other and thereby, groups the receivers rv included in the area pa into two groups. In this case, a group including the receivers rv-4 and rv-5 and the receiver rv3 are included in the same group. The calculating unit 305 calculates the evaluation value similar to the case for the vertical trunk wire w2 count n of four.

The selecting unit 306 compares the evaluation value for the combination for the vertical trunk wire w2 count n of three, with the evaluation value for the combination for the vertical trunk wire w2 count n of two. In this case, the evaluation value is smaller for the combination for the vertical trunk wire w2 count n of two and therefore, the calculating unit 305 calculates the evaluation value for the combination for the vertical trunk wire w2 count n of one.

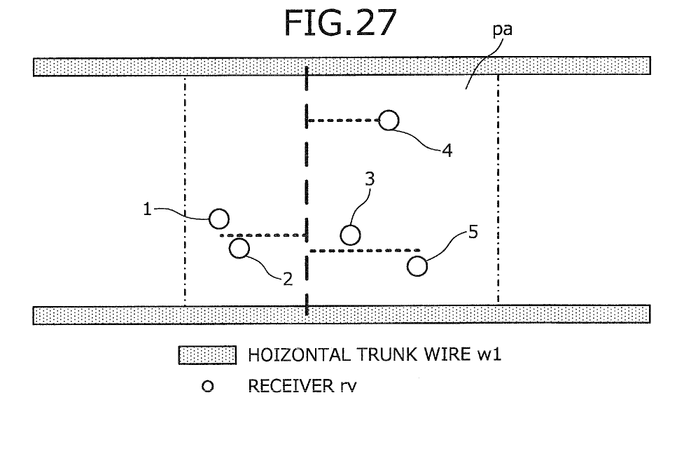

FIG. 27 is an explanatory diagram of an arrangement example of the vertical trunk wires for the number of vertical trunk wire of one. For the vertical trunk wire w2 count n of one, the calculating unit 305 consolidates all the receivers rv into one group and calculates the evaluation value similar to the case for the vertical trunk wire w2 count n of four.

The selecting unit 306 compares the evaluation value for the combination for the vertical trunk wire w2 count n of two, with the evaluation value for the combination for the vertical trunk wire w2 count n of one. The selecting unit 306 selects the combination whose evaluation value is the smaller as the optimal combination and, in this case, selects, for example, the combination for the vertical trunk wire w2 count n of two as the optimal combination.

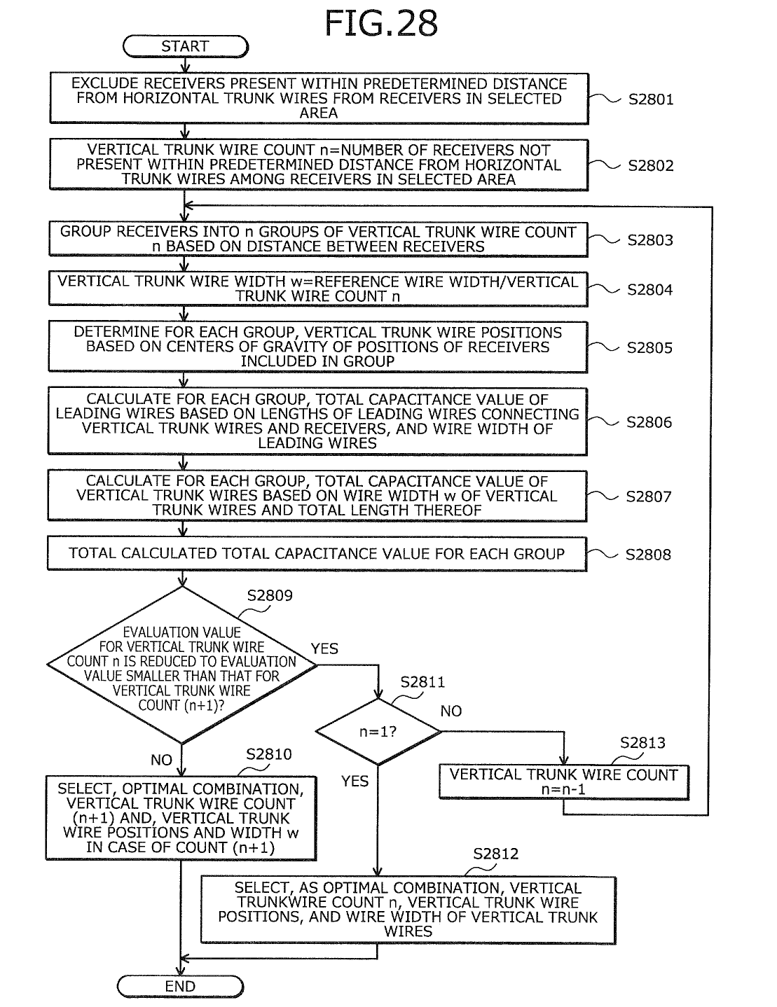

FIG. 28 is a flowchart of an example of the procedure for the determining process executed by the design support apparatus according to the second example. The overall procedure for the design support process executed by the design support apparatus 100 is same as the procedure depicted in FIG. 19 and will not again be described in detail. The design support apparatus 100 first excludes the receivers rv present within a predetermined distance from the horizontal trunk wires w1 from the receivers rv in the selected area pa (step S2801), and sets the vertical trunk wire w2 count n to be “the vertical trunk wire w2 count n=the number of receivers rv not present within the predetermined distance from the horizontal trunk wires w1 among the receivers rv in the selected area pa” (step S2802).

The design support apparatus 100 groups the receivers rv not present within the predetermined distance from the horizontal trunk wires w1 of the receivers in the selected area pa, into n groups of the vertical trunk wire w2 count n based on the distance between the receivers rv (step S2803), and sets the wire width w of the vertical trunk wires w2 to be “the wire width w of the vertical trunk wires w2=the reference wire width/the vertical trunk wire w2 count n (step S2804).

The design support apparatus 100 determines for each of the groups, the vertical trunk wire w2 positions based on the centers of gravity of the positions of the receivers rv included in the group (step S2805), and calculates for each of the groups, the total capacitance value of the leading wires based on the lengths of the leading wires connecting the vertical trunk wires w2 and the receivers rv, and the wire width w of the leading wires (step S2806).

The design support apparatus 100 calculates for each of the groups, the total capacitance value of the vertical trunk wires based on the wire width w of the vertical trunk wires w2 and the total length thereof (step S2807), totals the calculated total capacitance value for each of the groups (step S2808), and determines whether the evaluation value for the vertical trunk wire w2 count n is reduced to an evaluation value smaller than that for the count (n+1) of vertical trunk wires w2 (step S2809). If the design support apparatus 100 determines that the evaluation value for the vertical trunk wire w2 count n is not reduced to an evaluation value smaller than that for the count (n+1) of vertical trunk wires w2 (step S2809: NO), the design support apparatus 100 advances to the operation at step S2810, selects, as the optimal combination, the count (n+1) of vertical trunk wires w2, the vertical trunk wire w2 positions for the count (n+1) and the wire width w of the vertical trunk wires w2 for the count (n+1) (step S2810), and causes the series of operations to come to an end.

If the design support apparatus 100 determines that the evaluation value for the vertical trunk wire w2 count n is reduced to an evaluation value smaller than that for the count (n+1) of vertical trunk wires w2 (step S2809: YES), the design support apparatus 100 determines whether n is n=1 (step S2811). If the design support apparatus 100 determines that n is n=1 (step S2811: YES), the design support apparatus 100 selects the vertical trunk wire w2 count n, the vertical trunk wire w2 positions, and the wire width of the vertical trunk wires w2 as the optimal combination (step S2812) and causes the series of operations to come to an end. If the design support apparatus 100 determines that n is not n=1 (step S2811: NO), the design support apparatus 100 sets the vertical trunk wire w2 count n to be n=n−1 (step S2813) and returns to the operation at step S2803.

Not limited to the first and the second examples, the combinations of the vertical trunk wire w2 count N and the vertical trunk wire w2 positions may be determined using another method such as an anneal technique. According to the anneal technique, for example, when the determining unit 304 determines the vertical trunk wire w2 positions, the determining unit 304 moves the vertical trunk wire w2 positions based on random numbers to avoid any local solution, in a direction to obtain a smaller evaluation value calculated by the calculating unit 305 for the positions thereof. The determining unit 304 determines the optimal positions of the vertical trunk wires w2 by reducing any fluctuation due to the random numbers. This is effective for, for example, a case where the number of receivers rv is large.

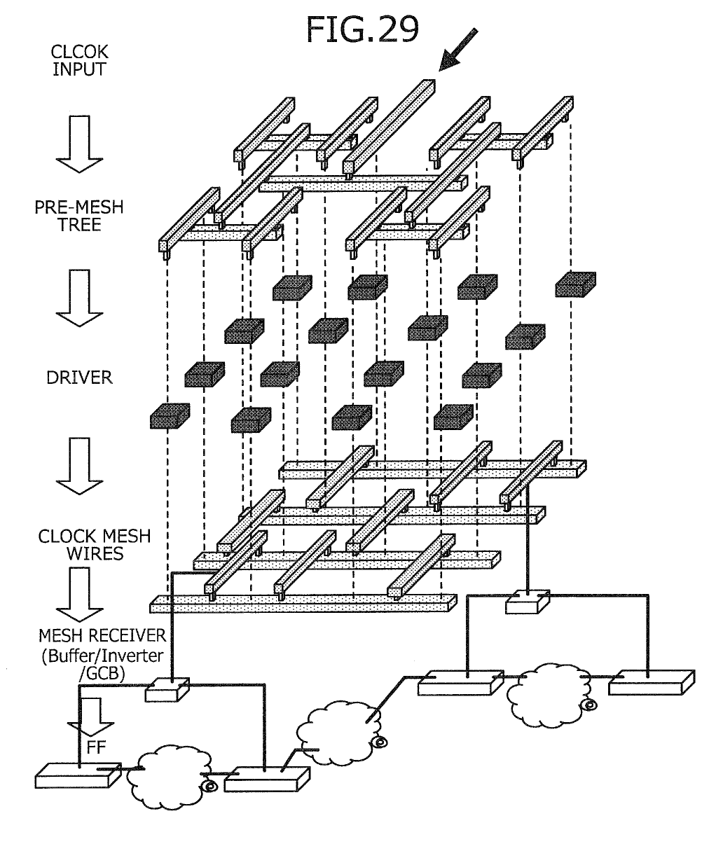

An arrangement example will be described of a semiconductor integrated circuit manufactured based on the layout data designed using the design support apparatus 100 with reference to FIGS. 29 to 41.

FIG. 29 is an explanatory diagram of a configuration example of the clock wires. From clock wires of a pre-mesh tree like an H-tree configuration and into which the clock signal is input, the clock signal is distributed to the drivers dr by employing the wiring that causes the clock signal to be distributed in the overall predetermined area “area”.

The drivers dr output the clock signal to the horizontal trunk wires w1 that connect the outputs to each other. Clock buffers and gated clock buffers (GCBs) to be the receivers rv receive the clock signal from the clock mesh wires. The receivers rv further output the clock signal to the FFs, etc. The case may be present where the clock mesh wires are directly connected to the FFs and thereby, the clock signal is propagated. In this manner, the clock signal is output to the FFs and thereby, the circuit to be designed is formed.

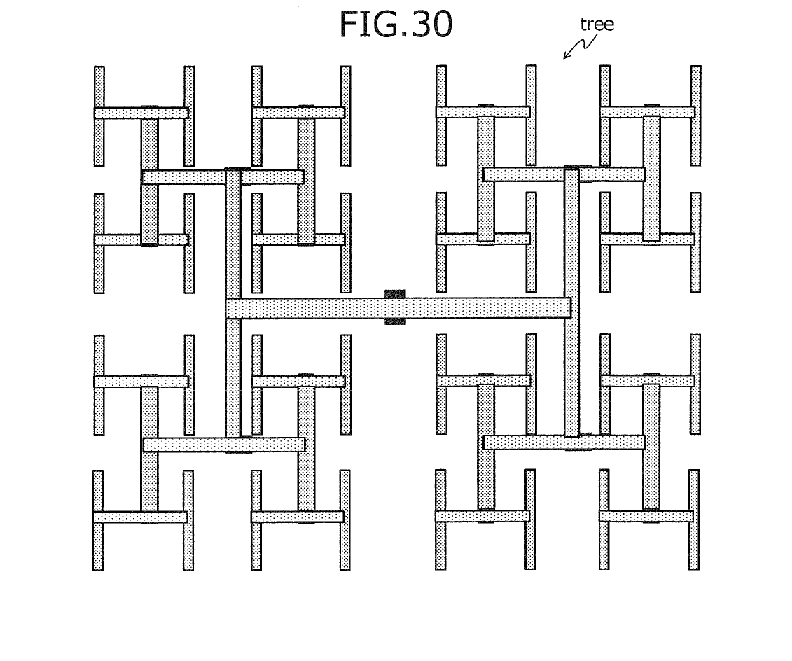

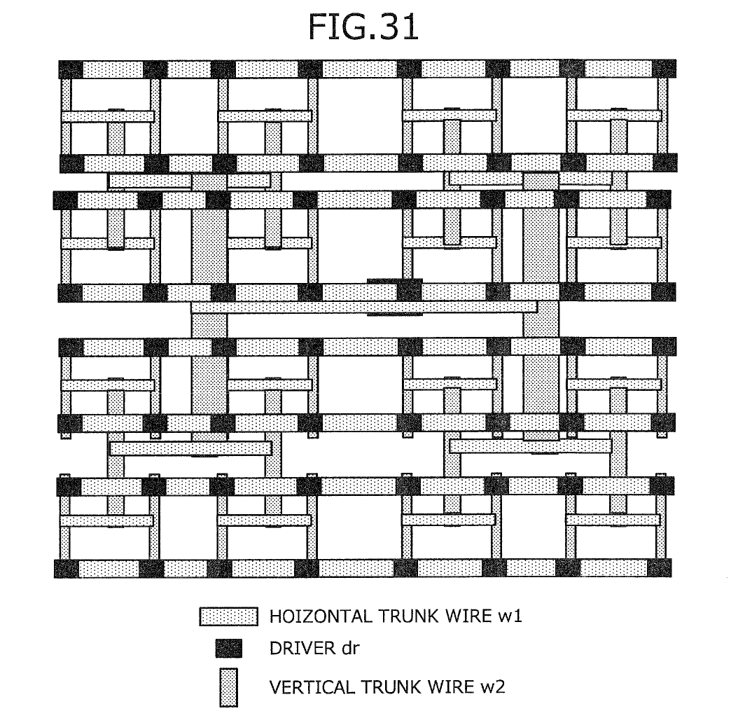

FIG. 30 is an explanatory diagram of an example of the pre-mesh tree. FIG. 31 is an explanatory diagram of an example where the pre-mesh tree and the clock mesh wires are overlapped with each other. The driver dr such as the clock buffer is disposed at each position of the H-tree and thereby, the pre-mesh tree “tree” is formed.

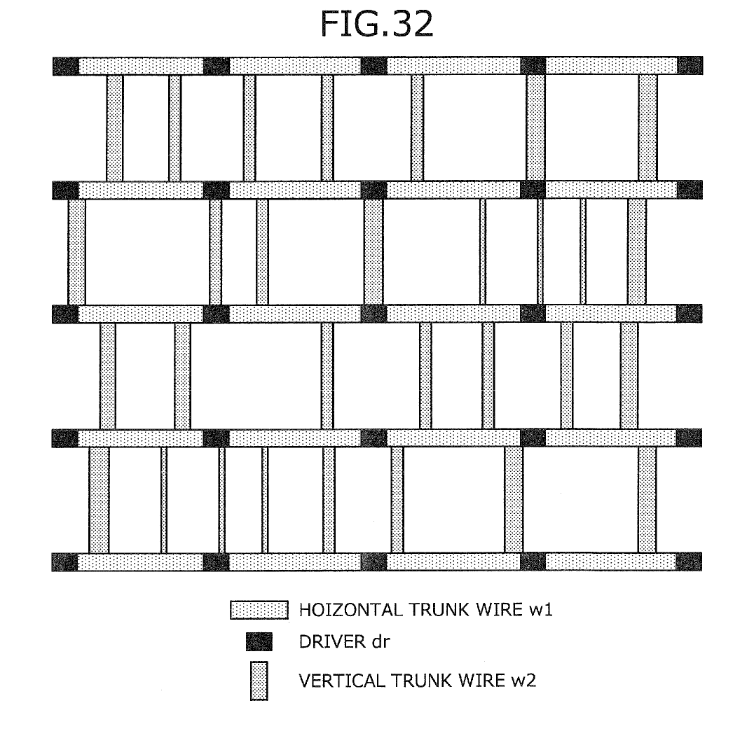

FIG. 32 is an explanatory diagram of a configuration example of the clock mesh wires and the drivers. The drivers dr are disposed along the horizontal trunk wires w1, and output the clock signal to the horizontal trunk wires w1. The vertical trunk wires w2 connect the horizontal trunk wires w1 and thereby, the differences can be reduced in the delay of the clock signal propagated between the horizontal trunk wires w1.

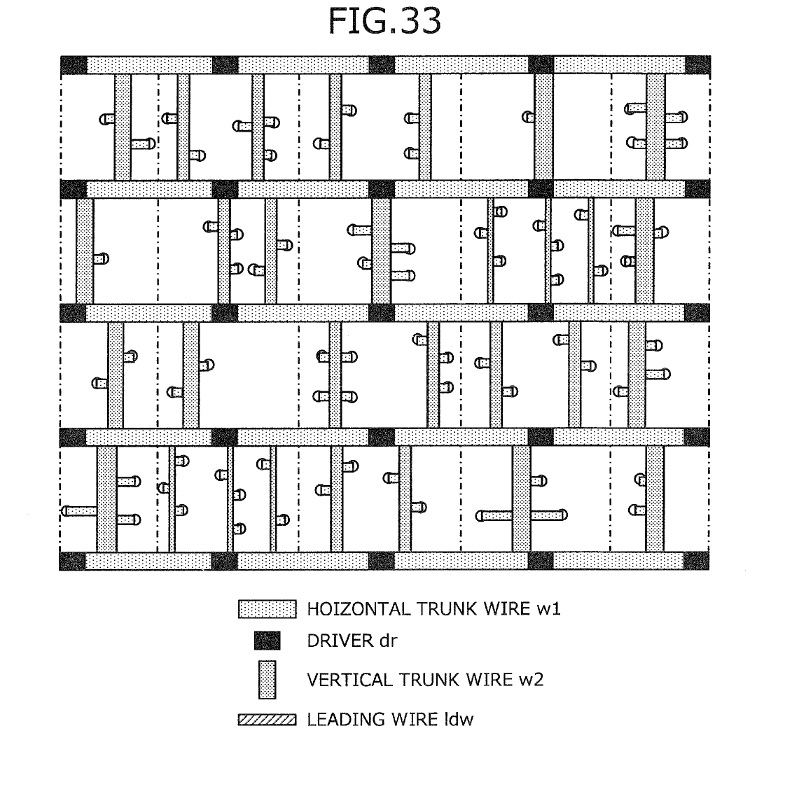

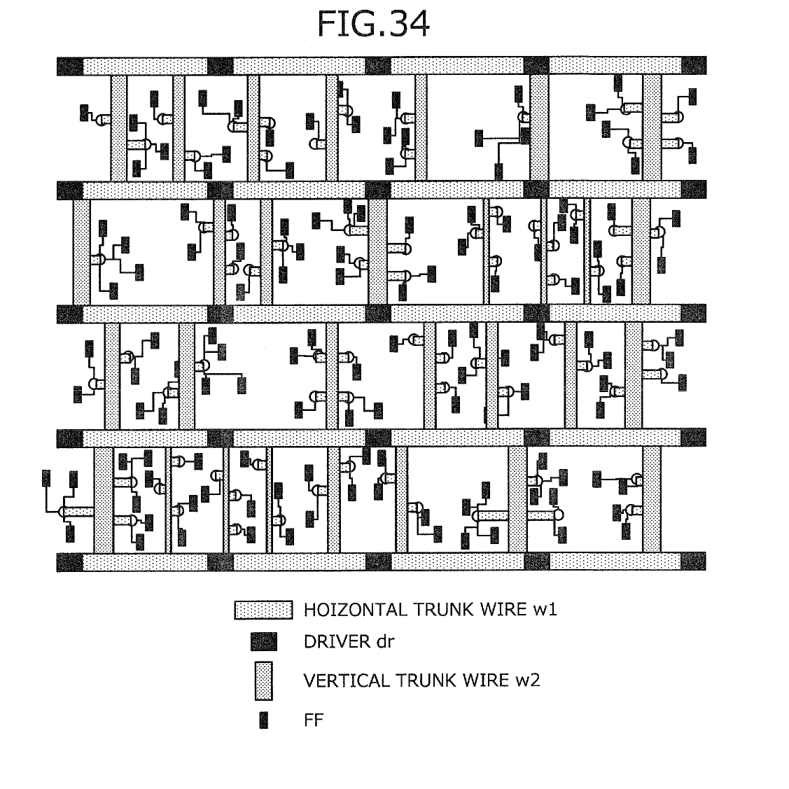

FIG. 33 is an explanatory diagram of a configuration example of the clock mesh wires, the receivers, and the drivers. As depicted in FIG. 33, the semiconductor integrated circuit according to the embodiment includes plural partial areas. Each of the plural partial areas includes the plural receivers rv, the horizontal trunk wires w1 that are the first clock wires, and the vertical trunk wires w2 that are the second clock wires perpendicular to the horizontal trunk wires w1, and further includes a circuit to which the clock signal is supplied through at least one of the plural receivers rv and the leading wire. In a first partial area of the plural partial areas, the number of vertical trunk wire w2 is one and the wire width thereof is the reference wire width. In a second partial area of the plural partial areas, the vertical trunk wire w2 count N is n (“n” is an integer greater than or equal to two) and the wire widths of the n vertical trunk wires w2 each differ from the reference wire width. In the second partial area, the total of the wire widths of the n vertical trunk wires w2 is equal to the reference wire width and the value of the wire width of each of the n vertical trunk wires w2 is equal to a value obtained by dividing the value of the reference wire width by n.

Wires are present that connect the vertical trunk wires w2 and the receivers rv. For the receiver rv whose distance to the horizontal trunk wire w1 is shorter than that to the vertical trunk wire w2, the horizontal trunk wire w1 and the receiver rv may be connected to each other.

FIG. 34 is an explanatory diagram of a configuration example of the wires from the clock mesh wires to the FFs. The clock signal is propagated to the FFs through the receivers rv by the leading wires 1dw that connect the receivers rv and the FFs. The leading wires 1dw may be present that connect the FFs and the vertical trunk wires w2 without using any receiver rv.

The semiconductor integrated circuit includes the leading wires 1dw connecting the plural receivers rv and the vertical trunk wires w2, and also includes the FFs that each are a circuit to which the clock signal is supplied through at least one of the plural receivers rv and the leading wire 1dw. Among the plural partial areas, the vertical trunk wire w2 count N differs corresponding to the total of the lengths of the leading wires 1dw included in the corresponding partial area; the vertical trunk wire w2 positions differ corresponding to the total of the lengths of the leading wires 1dw included in the corresponding partial area; the vertical trunk wire w2 count N the vertical trunk wire w2 count N differs corresponding to the total of the capacitance values of the leading wires 1dw included in the corresponding partial area; and the vertical trunk wire w2 positions differ corresponding to the total of the capacitance values of the leading wires 1dw included in the corresponding partial area.

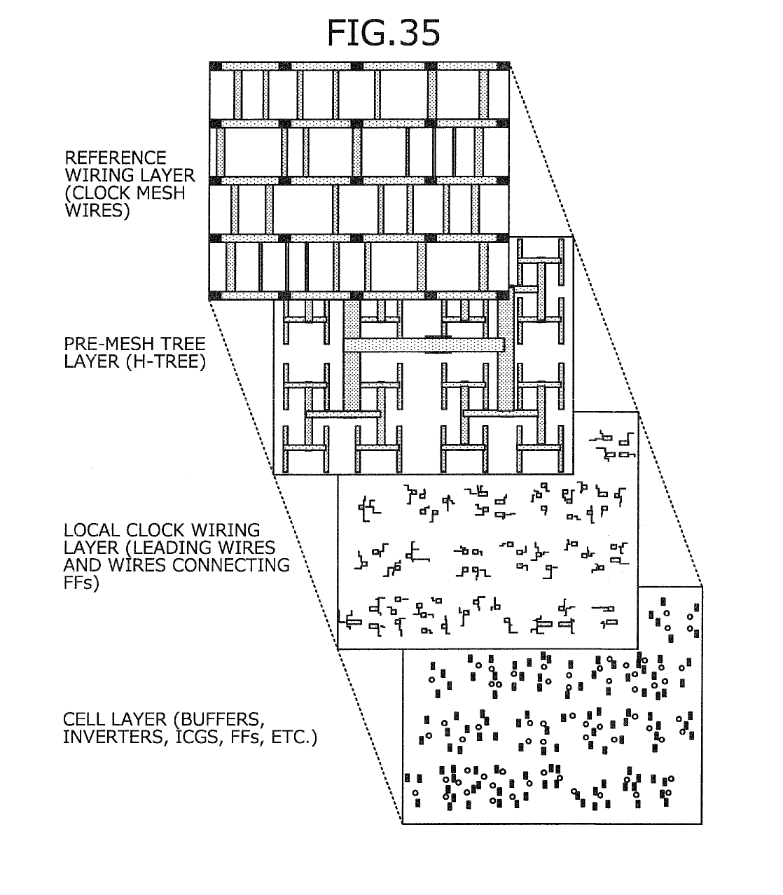

FIG. 35 is an explanatory diagram of a layer structure example. The circuit to be designed includes a reference wiring layer having the clock mesh wires formed therein, a pre-mesh tree layer having an H-tree formed therein, and a local clock wiring layer having the leading wires and the wires connecting the FFs formed therein, and further includes a cell layer having cells such as buffers, inverters, ICGs, the FFs, etc., formed therein. As described above, the structures such as the pre-mesh, the mesh wires, etc., are structured using the plural layers.

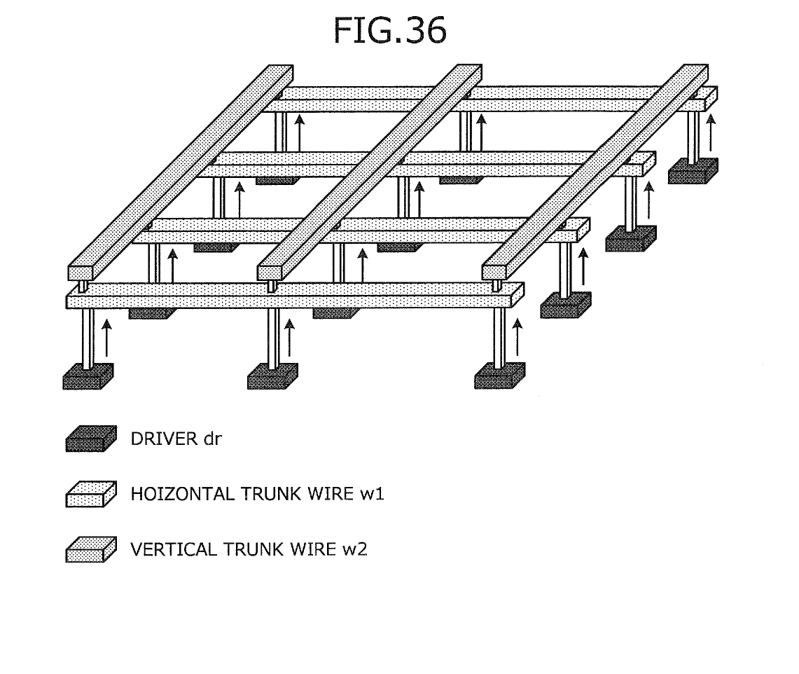

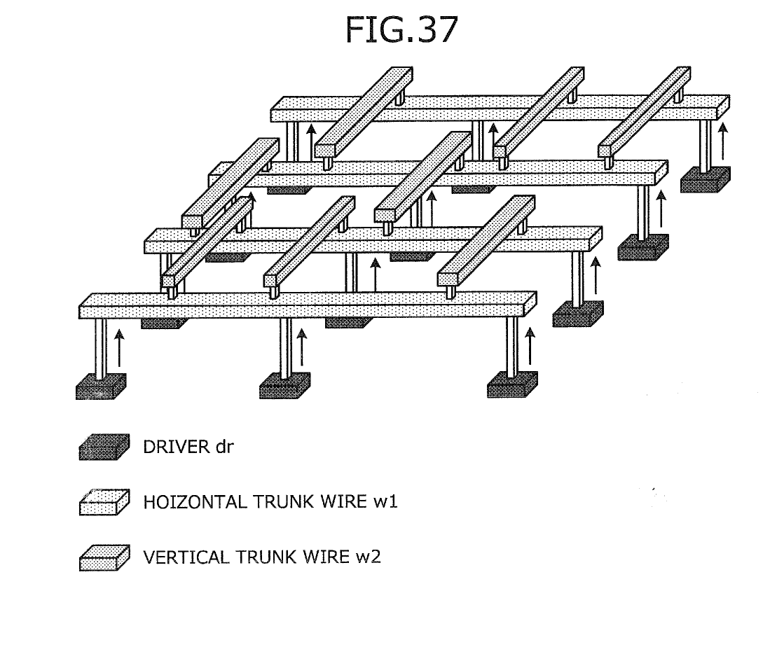

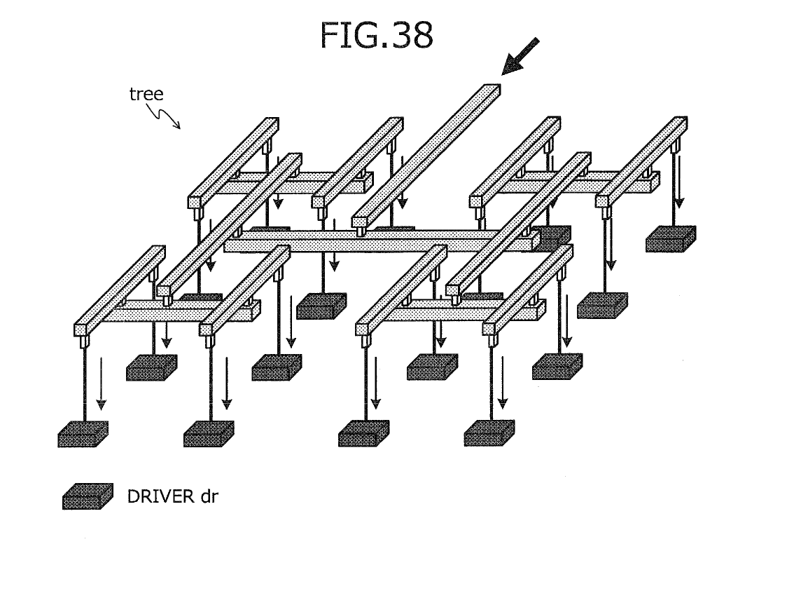

FIG. 36 is a three-dimensional explanatory diagram of a structure example of the clock mesh wiring for a case where the vertical trunk wires are regularly disposed. FIG. 37 is a three-dimensional explanatory diagram of a structure example of the clock mesh wires for a case where the vertical trunk wires in the embodiment are disposed. The vertical trunk wires w2 and the horizontal trunk wires w1 are conventionally disposed regularly as depicted in FIG. 36. In contrast, in the embodiment, the plural horizontal trunk wires w1 are disposed that connect the outputs of the plural drivers dr as depicted in FIG. 37. The vertical trunk wires w2 connecting the horizontal trunk wires w1 are disposed such that the resistance value between the horizontal trunk wires w1 is less than or equal to a specific value. The vertical trunk wires w2 are not always disposed regularly and are placed in the circuit under design corresponding to the positions of the receivers rv.

FIG. 38 is a three-dimensional explanatory diagram of a structure example of the pre-mesh tree. As depicted in FIG. 38, in the pre-mesh tree “tree” like the H-tree, the clock signal can evenly be distributed to the drivers dr in the predetermined area “area”.

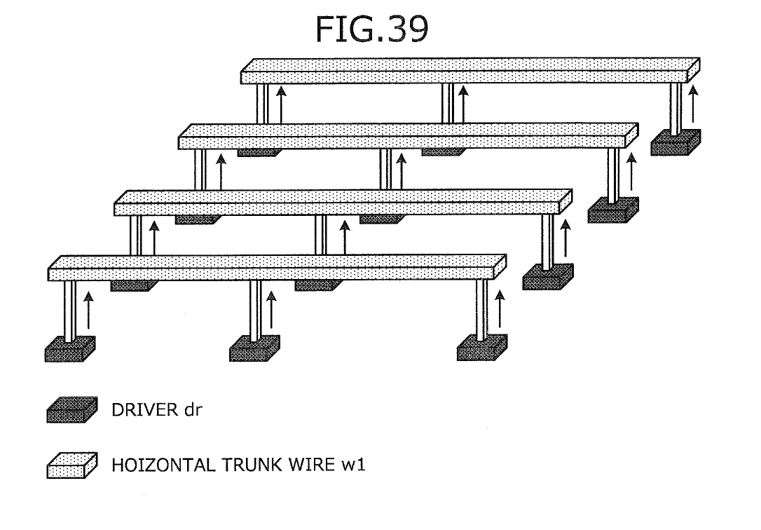

FIG. 39 is a three-dimensional explanatory diagram of a structure example of the horizontal trunk wires and the drivers. The drivers dr are disposed along the horizontal trunk wires w1 and thereby, the plural drivers dr output the clock signal to the same horizontal trunk wire w1.

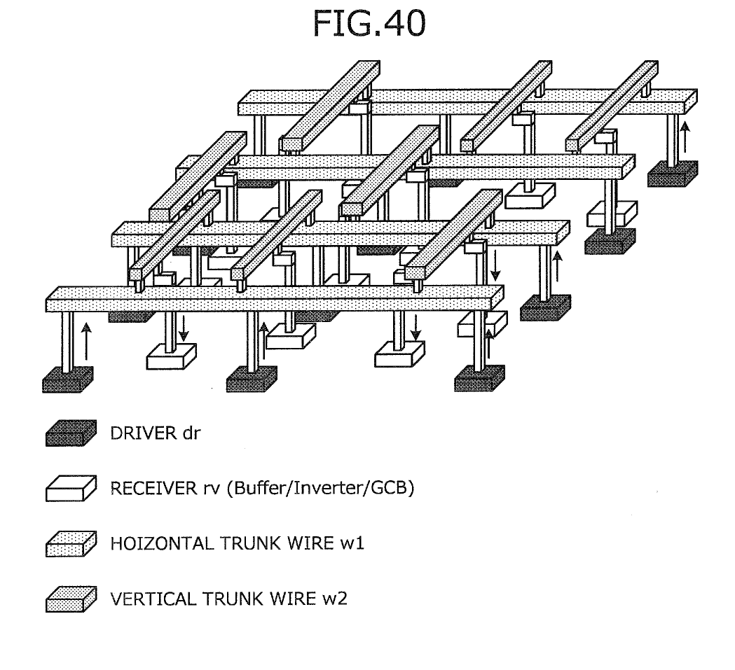

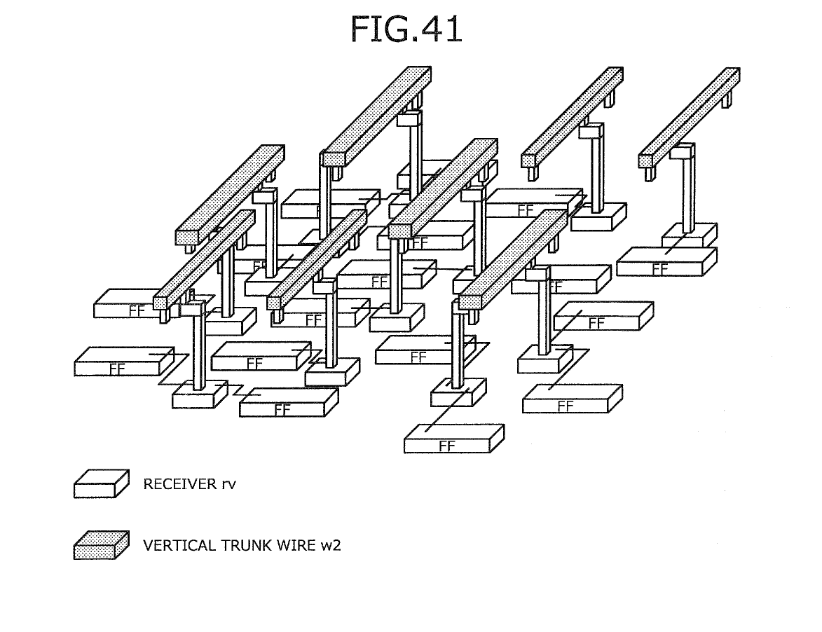

FIG. 40 is a three-dimensional explanatory diagram of a structure example of the clock mesh wires, the drivers, and the receivers. The vertical trunk wires w2 are determined corresponding to the positions of the receivers rv and propagate the clock signal to the receivers rv.

FIG. 41 is a three-dimensional explanatory diagram of a structure example of the clock mesh wires, the receivers, and the FFs. The vertical trunk wires w2 propagate the clock signal to the receivers rv. The receivers rv output the clock signal to the FFs. Not limited hereto, the vertical trunk wires w2 or the horizontal trunk wires w1 may be connected to the FFs.

As described above, in the design of the clock mesh wiring, the design support apparatus 100 calculates the evaluation value corresponding to the lengths of the wires connecting the receivers to the vertical trunk wires for the combinations of the number of vertical trunk wires and the positions thereof. Thereby, the number of vertical trunk wires and the positions thereof needing a small wiring amount can be selected. Therefore, reduction of the wiring amount can be facilitated. The reduction of the wiring amount enables further reduction of the differences in clock skew, reduction of the power consumption, and improvement of the wiring properties.

The design support apparatus 100 sets the number of vertical trunk wires to be is less than or equal to the number of receivers. Thereby, the number of combinations of the number of vertical trunk wires and the positions thereof can be reduced and an increase of the speed of the calculation process executed by the design support apparatus can be facilitated. The horizontal trunk wires are included in the wiring layer different from that of the vertical trunk wires.

The design support apparatus 100 sets the wire width of the vertical trunk wires to be a wire width corresponding to the number of second clock wires. Thus, regardless of the number of vertical trunk wires, the value of the combined resistance of the vertical trunk wires between the horizontal trunk wires in the partial area can be set to be constant, and the differences can be reduced. Therefore, differences in clock skew can be further reduced.

The design support apparatus 100 selects any one of the combinations of the number of vertical trunk wires and the positions thereof, based on the evaluation value thereof. Thereby, the combination of the number of vertical trunk wires and the positions thereof with a small wiring amount can be reported automatically to the user.

The evaluation value is the total length of the wires. Thereby, comparisons of the magnitudes between the wiring amounts can be executed with a small calculation amount.

The design support apparatus 100 selects any one of the plural combinations based on the total length calculated for each of the plural combinations, and selects the combination whose calculated total length is the shortest. Thereby, the combination of the number of vertical trunk wires and the positions thereof with a small wiring amount can automatically be informed of to the user.

For each of the plural combinations, the design support apparatus 100 calculates as the evaluation value the total value of the total length of the wires and the total length of the second clock wires. Thereby, comparisons of the magnitudes between the wiring amounts can be executed with a small calculation amount.

For each of the plural combinations, the design support apparatus 100 calculates the total value of: the total capacitance value of the leading wires; and the total capacitance value of the second clock wires based on the wire widths of the second clock wires and the total length thereof. The total capacitance value of the leading wires is the value based on the width of the leading wires and a value corresponding to the calculated length. The wire width of the second clock wires is determined corresponding to the number of second clock wires. Thus, comparisons of the magnitudes between the wiring amounts can accurately be executed.

The design support apparatus 100 selects any one of the plural combinations based on the total value calculated for each of the plural combinations, and selects the combination whose calculated total value is the smallest. Thereby, the combination of the number of vertical trunk wires and the positions thereof with a small wiring amount can be reported automatically to the user.

The design support apparatus 100 calculates the value for each of the plural combinations of the number of second clock wires, and the positions thereof based on the centers of gravity of the receivers connected to the second clock wires. Thereby, the positions of the second clock wires can be set to be the positions whose distances to any one of the receivers connected to the second clock wires is short.

According to the semiconductor integrated circuit according to the embodiment, in the first partial area of the plural partial areas, the number of vertical trunk wire is one and the wire width of the vertical trunk wire is the reference wire width; and in the second partial area of the plural partial areas, the number of vertical trunk wires is n (“n” is an integer greater than or equal to two) and the wire widths of the n vertical trunk wires each differ from the reference wire width. Thereby, the value of the combined resistance of the vertical trunk wires between the horizontal trunk wires in the partial area can be set to be constant and differences thereof can be reduced. Therefore, differences in clock skew can be reduced further. The wire capacitance of the leading wires can also be reduced.

In the second partial area, the total of the wire widths of the n second clock wires is equal to the reference wire width, and the value of the wire width of each of the n vertical trunk wires is equal to the value obtained by dividing the value of the reference wire width by n. Thereby, the value can be set to be constant of the combined resistance of the vertical trunk wires between the horizontal trunk wires in the partial area regardless of the number of vertical trunk wires and thereby, differences thereof can be reduced. Thus, differences in clock skew can further be reduced.

Among the plural partial areas, the number of vertical trunk wires differs corresponding to the total length of the leading wires included in the corresponding partial area. Thus, the value of the combined resistance of the vertical trunk wires between the horizontal trunk wires in the partial area can be set to be constant, whereby differences thereof can further be reduced.

Among the plural partial areas, the positions of vertical trunk wires differs corresponding to the total length of the leading wires included in the corresponding partial area. Thus, the value of the combined resistance of the vertical trunk wires between the horizontal trunk wires in the partial area can be set to be constant, whereby differences thereof can further be reduced.

Among the plural partial areas, the number of vertical trunk wires differs corresponding to the total capacitance of the leading wires included in the corresponding partial area. Thus, the value of the combined resistance of the vertical trunk wires between the horizontal trunk wires in the partial area can be set to be constant, whereby differences thereof can further be reduced.

Among the plural partial areas, the positions of vertical trunk wires differs corresponding to the total capacitance of the leading wires included in the corresponding partial area. Thus, the value of the combined resistance of the vertical trunk wires between the horizontal trunk wires in the partial area can be set to be constant, whereby differences thereof can further be reduced.

The circuit design support method described in the present embodiment may be implemented by executing a prepared program on a computer such as a personal computer and a workstation. The program is stored on a non-transitory, computer-readable recording medium such as a magnetic disk, an optical disk, universal serial bus (USB) flash memory, etc., read out from the computer-readable medium, and executed by the computer. The program may be distributed through a network such as the Internet.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A circuit design support method comprising:
obtaining layout data that indicates positions of a plurality of clock receivers disposed in a circuit and positions of first clock wires disposed in the circuit; and
calculating, by a computer, a value corresponding to lengths of wires respectively connecting the clock receivers to second clock wires on the basis of the obtained layout data, the value being calculated for each of a plurality of combinations of a count of the second clock wires and positions of the second clock wires, the second clock wires being disposed in a wiring layer of the circuit and being perpendicular to the first clock wires.

2. The circuit design support method according to claim 1, wherein
the second clock wires are disposed in a wiring layer different from a wiring layer of the first clock wires.

3. The circuit design support method according to claim 1, wherein
the count of the second clock wires is less than or equal to a count of the clock receivers.

4. The circuit design support method according to claim 1, wherein
a wire width of the second clock wires is a wire width corresponding to the count of the second clock wires.

5. The circuit design support method according to claim 1, further comprising
selecting any one combination from the plurality of combinations on the basis of the value corresponding to the lengths and calculated for each of the plurality of combinations.

6. The circuit design support method according to claim 1, wherein
the value corresponding to the lengths is a total length of the wires.

7. The circuit design support method according to claim 6, further comprising
selecting any one combination from the plurality of combinations on the basis of the total length calculated for each of the plurality of combinations.

8. The circuit design support method according to claim 7, wherein
the selecting includes selecting a combination whose calculated total length is shortest.

9. The circuit design support method according to claim 5, further comprising
calculating a total value of a total length of the wires and a total length of the second clock wires, for each of the plurality of combinations.

10. The circuit design support method according to claim 1, further comprising
calculating, for each of the plurality of combinations, a total value of a first total capacitance value of the wires and a second total capacitance value of the second clock wires, the first total capacitance value being based on a width of each of the wires and the calculated value corresponding to the lengths, the second total capacitance value being based on a width of each of the second clock wires determined in accordance with the count of second clock wires and a total length of the second clock wires.

11. The circuit design support method according to claim 10, further comprising
selecting a combination from the plurality of combinations on the basis of the total value calculated for each of the plurality of combinations.

12. The circuit design support method according to claim 11, wherein
the selecting includes selecting a combination whose calculated total value is smallest.

13. The circuit design support method according to claim 1, wherein
the calculating includes calculating the value for each of the plurality of combinations of the count of the second clock wires and positions of the second clock wires, the positions of the second clock wires being based on centroids of the clock receivers connected to the second clock wires.

14. A non-transitory, computer-readable recording medium storing a circuit design support program that causes a computer to execute a process comprising:
obtaining layout data that indicates positions of a plurality of clock receivers disposed in a circuit and positions of first clock wires disposed in the circuit; and
calculating a value corresponding to lengths of wires respectively connecting the clock receivers to second clock wires on the basis of the obtained layout data, the value being calculated for each of a plurality of combinations of a count of the second clock wires and positions of the second clock wires, the second clock wires being disposed in a wiring layer of the circuit and being perpendicular to the first clock wires.

15. A circuit design support apparatus comprising
a processor configured to:
obtain layout data that indicates positions of a plurality of clock receivers disposed in a circuit and positions of first clock wires disposed in the circuit; and
calculate a value corresponding to lengths of wires respectively connecting the clock receivers to second clock wires on the basis of the obtained layout data, the value being calculated for each of a plurality of combinations of a count of the second clock wires and positions of the second clock wires, the second clock wires being disposed in a wiring layer of the circuit and being perpendicular to the first clock wires.

16. A semiconductor integrated circuit comprising
a plurality of partial areas, wherein
each of the plurality of partial area includes:
a plurality of clock receivers;
a first clock wire;
a second clock wire disposed in a direction perpendicular to a direction of the first clock wires;
a plurality of leading wires that connect the plurality of clock receivers and the second clock wire; and
a circuit to which a clock signal is supplied through at least one of the plurality clock receivers and a leading wire,
in a first partial area among the plurality of partial areas, a count of the second clock wire is one and a wire width of the second clock wire is a reference wire width, and
in a second partial area among the plurality of partial areas, the count of the second clock wire is “n” (where, n is an integer of two or more) and a wire width of each of the n second clock wires is different from the reference wire width.

17. The semiconductor integrated circuit according to claim 16, wherein
in the second partial area, a total of the wire widths of the n second clock wires is equal to the reference wire width.

18. The semiconductor integrated circuit according to claim 16, wherein
in the second partial area, the wire widths of the n second clock wires are equal to the reference wire width divided by n.

19. The semiconductor integrated circuit according to claim 16, wherein
the count of the second clock wire is different for each of the plurality of partial areas, in accordance with a total of lengths of the leading wires included in a corresponding one of the plurality of partial areas.

20. The semiconductor integrated circuit according to claim 16, wherein
a position of the second clock wire is different for each of the plurality of partial areas, in accordance with a total of lengths of the leading wires included in a corresponding one of the plurality of partial areas.

21. The semiconductor integrated circuit according to claim 16, wherein
the count of the second clock wire is different for each of the plurality of partial areas, in accordance with a total capacitance of the leading wires included in a corresponding one of the plurality of partial areas.

22. The semiconductor integrated circuit according to claim 16, wherein
a position of the second clock wire is different for each of the plurality of partial areas, in accordance with a total capacitance of the leading wires included in a corresponding one of the plurality of partial areas.
